(19) United States
(12) Patent Application Publication
(10) Pub. No.: US 2026/0342300 A1
(43) Pub. Date: Oct. 29, 2026

(54) BALANCED AMPLIFIER CIRCUIT AND ELECTRONIC DEVICE INCLUDING THE SAME

(71) Applicant: SAMSUNG ELECTRONICS CO., LTD., Suwon-si (KR)

(72) Inventors: GeonHo PARK, Suwon-si (KR); Kyunghwan KIM, Suwon-si (KR); Byeongtaek MOON, Suwon-si (KR); Hyunchul PARK, Suwon-si (KR)

(73) Assignee: SAMSUNG ELECTRONICS CO., LTD., Suwon-si (KR)

(21) Appl. No.: 19/539,859

(22) Filed: Feb. 13, 2026

(30) Foreign Application Priority Data
Apr. 28, 2025 (KR) 10-2025-0055609

(51) Int. Cl. H03F 3/45; H03F 3/24; H03F 3/60

(52) U.S. Cl. CPC H03F 3/45475; H03F 3/245; H03F 3/602; H03F 2200/387

(57) ABSTRACT

A balanced amplifier circuit includes a first conversion circuit configured to output, based on an input signal having an input impedance, a first-first signal, a first-second signal, a second-first signal, and a second-second signal, a first amplifier circuit configured to output a first-third signal and a first-fourth signal, a second amplifier circuit configured to output a second-third signal and a second-fourth signal, and a second conversion circuit configured to output an output signal, having an output impedance, based on the first-third signal, the first-fourth signal, the second-third signal, and the second-fourth signal. Each of the first-first signal, the first-second signal, the second-first signal, and the second-second signal has a target input impedance. The first-first signal has a 90-degree phase difference from the second-first signal. The first-second signal has a differential relationship with the first-first signal. The second-second signal has a differential relationship with the second-first signal.

### CROSS-REFERENCE TO RELATED APPLICATIONS

This application claims priority under 35 U.S.C. § 119 to Korean Patent Application No. 10-2025-0055609, filed on Apr. 28, 2025, in the Korean Intellectual Property Office, the disclosure of which is incorporated by reference herein in its entirety.

### BACKGROUND

### 1. Field

The present disclosure relates generally to amplifier circuits, and more particularly, to a balanced amplifier circuit and an electronic device including the balanced amplifier circuit.

### 2. Description of Related Art

Attempts to meet increasing demands for wireless data traffic, which may have resulted from the commercialization of 4^{th} generation (4G) communication systems, may include efforts to develop improved 5^{th} generation (5G) and/or pre-5G communication systems. Consequently, 5G and/or pre-5G communication systems may be referred to as Beyond 4G Networks and/or Post Long Term Evolution (LTE) systems.

The use of millimeter-wave (mmWave) bands (e.g., 28 gigahertz (GHz) and 60 GHz bands) in 5G communication systems may be considered to potentially achieve relatively high data transmission rates. Alternatively or additionally, in an attempt to potentially mitigate path loss and/or increase the propagation distance of radio waves in the mmWave band, technologies such as, but not limited to, beamforming, massive multiple-input multiple-output (massive MIMO), full dimensional MIMO (FD-MIMO), array antennas, analog beamforming, and/or large-scale antennas may be under discussion for potential use in the 5G communication systems.

For example, there may be a growing demand for amplifier circuits that may operate with relatively low sensitivity to changes in load impedance and/or enhanced output power, when transmitting signals in relatively high frequency bands. In such an example, a balanced amplifier circuit may be utilized. A balanced amplifier circuit may refer to an amplifier circuit that separates an input signal into in-phase (I) and quadrature (Q) signals (e.g., I/Q signals) that are orthogonal to each other, amplifies each of the separated signals, and combines the amplified signals for output.

### SUMMARY

One or more example embodiments of the present disclosure provide a balanced amplifier circuit that includes a circuit to output signals each having a target input impedance and a differential relationship and signals which have a 90-degree phase difference with each other, from an input signal having an input impedance.

Further, one or more example embodiments of the present disclosure provide a balanced amplifier circuit that reduces an area of a circuit that may be needed to implement the electronic device, when compared to related amplifier circuits.

According to an aspect of the present disclosure, a balanced amplifier circuit includes a first conversion circuit, a first amplifier circuit, a second amplifier circuit, and a second conversion circuit. The first conversion circuit is configured to output, based on an input signal having an input impedance, a first-first signal, a first-second signal, a second-first signal, and a second-second signal. The first amplifier circuit is configured to amplify the first-first signal to output a first-third signal, and amplify the first-second signal to output a first-fourth signal. The second amplifier circuit is configured to amplify the second-first signal to output a second-third signal, and amplify the second-second signal to output a second-fourth signal. The second conversion circuit is configured to output an output signal, having an output impedance, based on the first-third signal, the first-fourth signal, the second-third signal, and the second-fourth signal. Each of the first-first signal, the first-second signal, the second-first signal, and the second-second signal has a target input impedance. The first-first signal has a 90-degree phase difference from the second-first signal. The first-second signal has a first differential relationship with the first-first signal. The second-second signal has a second differential relationship with the second-first signal.

According to an aspect of the present disclosure, an electronic device includes a balanced amplifier circuit and a processor configured to control the balanced amplifier circuit. The balanced amplifier circuit is configured to amplify an input signal having an input impedance and to output an output signal having an output impedance. The balanced amplifier circuit includes a first conversion circuit, a first amplifier circuit, a second amplifier circuit, and a second conversion circuit. The first conversion circuit is configured to output, based on the input signal provided by the processor, a first-first signal, a first-second signal, a second-first signal, and a second-second signal. The first amplifier circuit is configured to amplify the first-first signal to output a first-third signal, and to amplify the first-second signal to output a first-fourth signal. The second amplifier circuit is configured to amplify the second-first signal to output a second-third signal, and to amplify the second-second signal to output a second-fourth signal. The second conversion circuit is configured to output the output signal, via an output node, based on the first-third signal, the first-fourth signal, the second-third signal, and the second-fourth signal. Each of the first-first signal, the first-second signal, the second-first signal, and the second-second signal has a target input impedance. The first-first signal has a 90-degree phase difference from the second-first signal. The first-second signal has a first differential relationship with the first-first signal. The second-second signal has a second differential relationship with the second-first signal.

According to an aspect of the present disclosure, a conversion circuit for outputting a plurality of output signals based on an input signal having an input impedance includes a first capacitor coupled between an input node configured to receive the input signal and a ground, a first inductor coupled between the input node and a first node, a first transformer coupled between the input node and a second node and between the input node and a third node, a second transformer coupled between the first node and a fourth node and between the first node and a fifth node, a third transformer coupled between the second node and the fourth node and between the third node and the fifth node, and a second capacitor coupled between the first node and the ground. Each of the plurality of output signals has a target input impedance and a 90-degree phase difference with respect to one another. A first-first output signal of the plurality of output signals is output from the second node. A first-second output signal of the plurality of output signals is output from the third node. A second-first output signal of the plurality of output signals is output from the fourth node. A second-second output signal of the plurality of output signals is output from the fifth node. The first-second output signal has a first differential relationship with the first-first output signal. The second-first output signal has a second differential relationship with the second-second output signal.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram showing an electronic device, according to an embodiment of the present disclosure;

FIG. 2A is a block diagram showing a balanced amplifier circuit, according to an embodiment of the present disclosure;

FIG. 2B is a block diagram showing a balanced amplifier circuit further including an input resistor and an output resistor, according to an embodiment of the present disclosure;

FIG. 3 is a circuit diagram showing a balanced amplifier circuit, according to an embodiment of the present disclosure;

FIG. 4 is a circuit diagram showing an equivalent circuit of a first conversion circuit of the balanced amplifier circuit of FIG. 3;

FIG. 5 is a circuit diagram showing a balanced amplifier circuit in which each of first and second amplifier circuits includes an amplifier, according to an embodiment of the present disclosure;

FIG. 6 is a circuit diagram showing a balanced amplifier circuit including a first conversion circuit, according to an embodiment of the present disclosure;

FIG. 7 is a circuit diagram showing a balanced amplifier circuit including a first conversion circuit, according to an embodiment of the present disclosure;

FIG. 8 is a circuit diagram showing a balanced amplifier circuit including a first conversion circuit, according to an embodiment of the present disclosure;

FIG. 9A is a circuit diagram showing a balanced amplifier circuit further including a third amplifier circuit, according to an embodiment of the present disclosure;

FIG. 9B is a circuit diagram showing a balanced amplifier circuit further including a third amplifier circuit receiving a differential signal, according to an embodiment of the present disclosure;

FIG. 10A is a flowchart showing a method of controlling an input signal based on a first power consumption consumed at an input node, according to an embodiment of the present disclosure;

FIG. 10B is a flowchart showing a method of controlling an input signal based on a second power consumption consumed at an output node, according to an embodiment of the present disclosure;

FIG. 11 is a block diagram showing an electronic device, according to an embodiment of the present disclosure;

FIG. 12 is a block diagram showing an Internet of Things (IoT) device including an electronic device, according to an embodiment of the present disclosure; and

FIG. 13 is a block diagram showing a mobile terminal to which an electronic device, according to an embodiment of the present disclosure, is applied.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

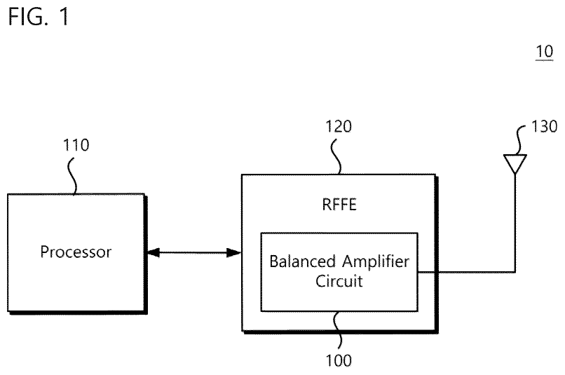

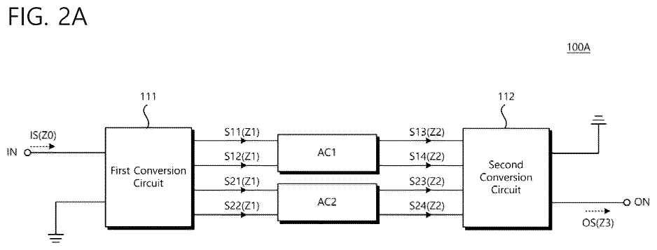

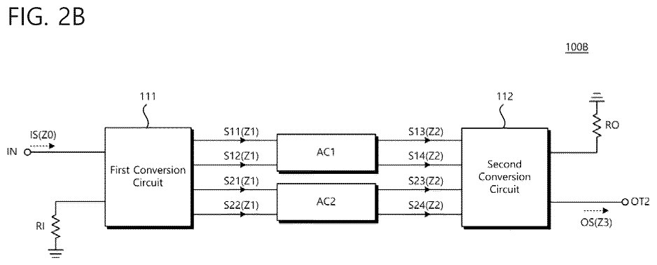

FIG. 1 is a block diagram showing an electronic device, according to an embodiment of the present disclosure. FIG. 2A is a block diagram showing a balanced amplifier circuit, according to an embodiment of the present disclosure. FIG. 2B is a block diagram showing a balanced amplifier circuit further including an input resistor and an output resistor, according to an embodiment of the present disclosure.

Referring to FIG. 1, the electronic device 10 may include a processor 110, a radio frequency front end (RFFE) 120, and an antenna 130.

The electronic device 10, according to various embodiments of the present disclosure, may be and/or may include various types of devices. For example, the electronic device 10 may include a portable communication device (e.g., a smartphone), a computer device, a portable multimedia device, a portable medical device, a camera, or a wearable device. However, embodiments of the present disclosure are not limited thereto, and the electronic device 10 may be and/or may include various other devices.

The electronic device 10 may include the antenna 130 that transmits and/or receives a radio frequency (RF) signal with a specified frequency. Accordingly, the electronic device 10, according to the present disclosure, may also be referred to as an antenna device, a wireless communication device, or a wireless transceiver, which includes the antenna 130.

The electronic device 10 may include the processor 110 for controlling the operation of the electronic device 10.

The processor 110, for example, may execute software and/or programs to control at least one other component of the electronic device 10 (e.g., the RFFE 120), and may perform various data processing and/or operations. The processor 110 may be and/or may include a central processing unit (CPU), a micro-processor, or the like and may control the overall operation of the electronic device 10. Therefore, operations performed by the electronic device 10 described below may be understood as being performed under the control of the processor 110.

According to an embodiment, the processor 110 may include an algorithm to control the RFFE 120 and/or the balanced amplifier circuit 100. For example, the algorithm may be and/or may include a software code programmed in the processor 110. As another example, the algorithm may be and/or may include a hard code that may be hard-coded in the processor 110. However, embodiments of the present disclosure are not limited thereto.

The processor 110 may control the RFFE 120, according to the algorithm, to provide a signal and/or power for transmitting the RF signal to the antenna 130. For example, the processor 110 may provide transmission power to the antenna 130 via the RFFE 120.

In such a manner, the processor 110 may transmit and/or receive signals in a specified frequency band through the antenna 130.

Accordingly, the processor 110, according to the present disclosure, may be referred to as a communication processor (CP).

In addition, the electronic device 10 may include the RFFE 120 connected between the processor 110 and the antenna 130. In the present disclosure, the RFFE 120 may include at least one of a phase shifter, a band-pass filter, and a mixer.

According to an embodiment, the RFFE 120 may include the balanced amplifier circuit 100. For example, the RFFE 120 may include the balanced amplifier circuit 100 connected to the antenna 130.

According to an embodiment, the electronic device 10 may further include a radio frequency integrated circuit (RFIC) connected between the RFFE 120 and the processor 110. In addition, the RFIC may include the balanced amplifier circuit 100 electrically connected to the antenna 130 via the RFFE 120.

That is, referring to the above-described configurations, the balanced amplifier circuit 100 may be included in the RFFE 120 or the RFIC. However, for the convenience of explanation below, it is assumed that the balanced amplifier circuit 100 is included in the RFFE 120.

Referring to FIGS. 1, 2A, and 2B, the balanced amplifier circuits 100, 100A, and 100B may amplify an input signal IS and output the amplified input signal IS as an output signal OS. In the present disclosure, the balanced amplifier circuit 100A, as shown in FIG. 2A, and the balanced amplifier circuit 100B, as shown in FIG. 2B may include and/or may be similar in many respects to the balanced amplifier circuit 100 shown in FIG. 1, and may include additional features. Consequently, repeated descriptions of the balanced amplifier circuits 100A and 100B described with reference to the balanced amplifier circuit 100 may be omitted for the sake of brevity.

For example, the balanced amplifier circuits 100, 100A, and 100B may amplify the amplitude of the input signal IS, which may be input through an input node IN, by a pre-specified gain and may output the amplified input signal IS as the output signal OS through an output node ON.

Referring to FIG. 2A, the balanced amplifier circuit 100A may include a first conversion circuit 111, a first amplifier circuit AC1, a second amplifier circuit AC2, and a second conversion circuit 112.

For example, the balanced amplifier circuit 100A may include the first conversion circuit 111 that outputs a plurality of signals (e.g., a first-first signal S11, a first-second signal S12, a second-first signal S21, and a second-second signal S22), from the input signal IS having an input impedance Z0. Each of the plurality of signals S11 to S22 may have a target input impedance Z1 and may have different phases.

In the present disclosure, the target input impedance Z1 may be an impedance that minimizes signals reflected as the signal is transmitted to the first amplifier circuit AC1 and the second amplifier circuit AC2. For example, the target input impedance Z1 may be approximately 50 ohms (Ω).

That is, the first conversion circuit 111 may perform an impedance-matching function to output, from the input signal IS having the input impedance Z0, the plurality of signals S11 to S22, each having the target input impedance Z1.

In addition, the first conversion circuit 111 may output signals in a differential relationship with each other from the single-phase input signal IS. For example, the first conversion circuit 111 may output a first-first signal S11 and a first-second signal S12, which are in a differential relationship, from the single-phase input signal IS.

Further, the first conversion circuit 111 may output signals, which have a 90-degree phase difference with each of the signals having the differential relationship. For example, the first conversion circuit 111 may output a second-first signal S21 that has the 90-degree phase difference with the first-first signal S11. In addition, the first conversion circuit 111 may output a second-second signal S22 that has the 90-degree phase difference with the first-second signal S12.

Referring to the configurations described above, the first conversion circuit 111 may output the mutually orthogonal plurality of signals S11 to S22, from the input signal IS. The input signal may have the input impedance Z0, and each of the plurality of signals S11 to S22 may have the target input impedance Z1.

That is, the first conversion circuit 111 may perform operations of converting the impedance of the input signal IS, outputting the signals S11 and S12, which are in the differential relationship, from the single-phase input signal IS, and outputting signals S11 and S21 having the 90-degree phase difference with each other.

Accordingly, the balanced amplifier circuit 100A, according to the present disclosure, may be implemented with a relatively smaller area compared to a case where a circuit for impedance conversion, a circuit to generate differential signals, and a circuit to generate signals having the 90-degree phase difference are provided separately.

That is, through the above-described configuration, the balanced amplifier circuit 100A, according to the present disclosure, may reduce the area that may be needed to implement the electronic device 10, when compared to related amplifier circuits.

In addition, the balanced amplifier circuit 100A may include the first amplifier circuit AC1 and the second amplifier circuit AC2.

That is, the balanced amplifier circuit 100A may include the first amplifier circuit AC1 that amplifies the first-first signal S11 and the first-second signal S12.

According to an embodiment, the first amplifier circuit AC1 may amplify the first-first signal S11 and the first-second signal S12 by a specified gain. For example, the first amplifier circuit AC1 may amplify the first-first signal S11 and may output the amplified first-first signal S11 as a first-third signal S13. In addition, the first amplifier circuit AC1 may amplify the first-second signal S12 and may output the amplified first-second signal S12 as a first-fourth signal S14.

The balanced amplifier circuit 100A may include the second amplifier circuit AC2 that amplifies the second-first signal S21 and the second-second signal S22.

According to an embodiment, the second amplifier circuit AC2 may amplify the second-first signal S21 and the second-second signal S22 by a specified gain. For example, the second amplifier circuit AC2 may amplify the second-first signal S21 and may output the amplified second-first signal S21 as a second-third signal S23. In addition, the second amplifier circuit AC2 may amplify the second-second signal S22 and may output the amplified second-second signal S22 as a second-fourth signal S24.

In the present disclosure, each of the first amplifier circuit AC1 and the second amplifier circuit AC2 may include at least one amplifier transistor to amplify a signal input thereto. Accordingly, each of the first amplifier circuit AC1 and the second amplifier circuit AC2 may be referred to as a transistor amplifier.

In addition, each of the first amplifier circuit AC1 and the second amplifier circuit AC2 may be referred to as a differential amplifier that amplifies signals (e.g., the first-first signal S11 and the first-second signal S12) in a differential relationship.

Each of the first-third signal S13, the first-fourth signal S14, the second-third signal S23, and the second-fourth signal S24 may have a target output impedance Z2. In the present disclosure, the target output impedance Z2 may be an impedance that minimizes signals reflected as the signals are transmitted from the first amplifier circuit AC1 and the second amplifier circuit AC2 to the second conversion circuit 112. For example, the target output impedance Z2 may be approximately 50 Ω.

Also, for example, the target output impedance Z2 and the target input impedance Z1 may have a substantially similar and/or the same value. However, embodiments of the present disclosure are not limited thereto.

The balanced amplifier circuit 100A may include the second conversion circuit 112 that outputs the output signal OS having an output impedance Z3 from the first-third to second-fourth signals S13 to S24, each having the target output impedance Z2 and the 90-degree phase difference from one another.

According to an embodiment, the second conversion circuit 112 may perform an impedance-matching function to output the output signal OS having the output impedance Z3 from the first-third to second-fourth signals S13 to S24, each having the target output impedance Z2.

In addition, the second conversion circuit 112 may output the single-phase output signal OS from the signals in a differential relationship with each other and from the signals having a 90-degree phase difference with each of the signals in the differential relationship.

That is, the second conversion circuit 112 may perform operations of converting the impedance of the signal input thereto and outputting the single-phase signal from the signals having different phases.

Accordingly, the balanced amplifier circuit 100A, according to the present disclosure, may be implemented with a relatively smaller area compared to a case where a circuit for impedance conversion and a circuit to generate the single-phase signal from the signals in the differential relationship and from the signals having the 90-degree phase difference with the signals in the differential relationship are provided separately.

That is, through the above-described configuration, the balanced amplifier circuit 100A, according to the present disclosure, may reduce the area that may be needed to implement the electronic device 10, when compared to related amplifier circuits.

In addition, the balanced amplifier circuit 100A, according to the present disclosure, may include a relatively smaller number of passive elements compared to a case where the circuit for impedance conversion and the circuit to generate the single-phase signal from the signals in the differential relationship and from the signals having the 90-degree phase difference with the signals in the differential relationship are provided separately.

Accordingly, the balanced amplifier circuit 100A, according to the present disclosure, may reduce power consumption due to the passive elements, when compared to related amplifier circuits. Further, the balanced amplifier circuit 100A may improve output power and gain, when compared to related amplifier circuits.

In addition, referring to the configurations described above, the balanced amplifier circuit 100A may amplify the signals having the 90-degree phase difference with each other using different first and second amplifier circuits AC1 and AC2.

Furthermore, the balanced amplifier circuit 100A may output the single-phase output signal OS having the output impedance Z3 from the first-third to second-fourth signals S13 to S24 output through the different first and second amplifier circuits AC1 and AC2.

Therefore, the electronic device 10 or the balanced amplifier circuit 100A, according to the present disclosure, may improve the output power, when compared to related amplifier circuits.

In addition, the electronic device 10 or the balanced amplifier circuit 100A, according to the present disclosure, may operate with less sensitivity to changes in load impedance by separately amplifying the signals having the 90-degree phase difference.

That is, the balanced amplifier circuit 100A, according to the present disclosure, may improve the performance of the RF signal transmission operation of the electronic device 10, when compared to related amplifier circuits.

Referring to FIG. 2B, the balanced amplifier circuit 100B may include a first conversion circuit 111, a first amplifier circuit AC1, a second amplifier circuit AC2, and a second conversion circuit 112. The balanced amplifier circuit 100B may further include an input resistor RI and an output resistor RO.

The balanced amplifier circuit 100B shown in FIG. 2B may include and/or may be similar in many respects to the balanced amplifier circuit 100A shown in FIG. 2A, and may include additional features not mentioned above. For example, the balanced amplifier circuit 100B may include the input resistor RI and the output resistor RO. Consequently, repeated descriptions of the balanced amplifier circuit 100B described above with reference to FIG. 2A may be omitted for the sake of brevity.

The balanced amplifier circuit 100B may include the input resistor RI connected between the first conversion circuit 111 and a ground. In the present disclosure, the input resistor RI may have a resistance value equal to approximately half of the target input impedance Z1. For example, the input resistor RI may have a resistance value of approximately 25 Ω.

In addition, the balanced amplifier circuit 100B may include the output resistor RO connected between the second conversion circuit 112 and the ground. In the present disclosure, the output resistor RO may have a resistance value equal to approximately half of the target output impedance Z2. For example, the output resistor RO may have a resistance value of approximately 25 Ω.

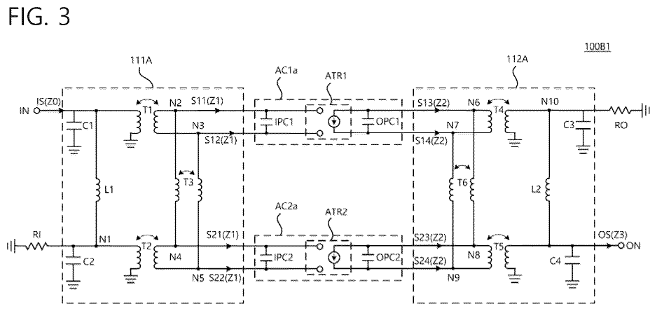

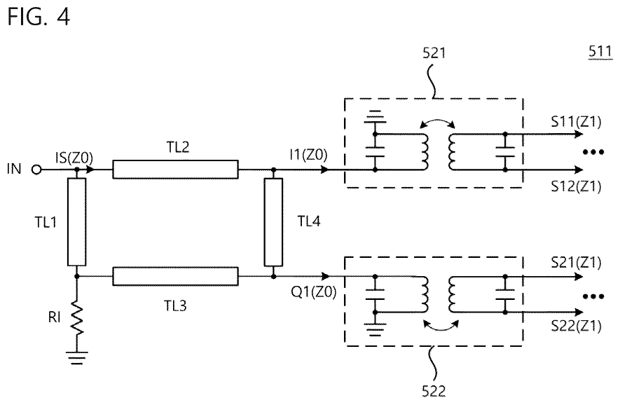

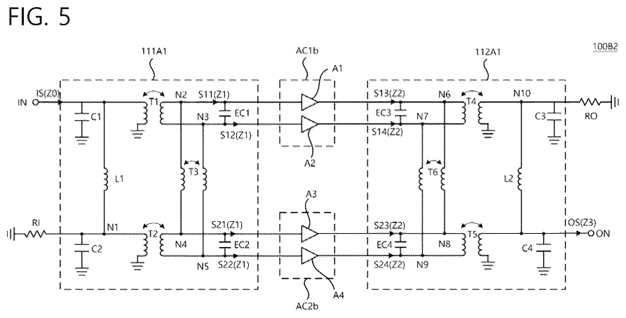

FIG. 3 is a circuit diagram showing a balanced amplifier circuit, according to an embodiment of the present disclosure. FIG. 4 is a circuit diagram showing an equivalent circuit of a first conversion circuit of the balanced amplifier circuit of FIG. 3. FIG. 5 is a circuit diagram showing a balanced amplifier circuit in which each of first and second amplifier circuits includes an amplifier, according to an embodiment of the present disclosure.

Referring to FIG. 3, the balanced amplifier circuit 100B1 may include a first conversion circuit 111A, a first amplifier circuit AC1a, a second amplifier circuit AC2a, and a second conversion circuit 112A. In the present disclosure, the balanced amplifier circuit 100B1, and its components, as shown in FIG. 3 may include and/or may be similar in many respects to the balanced amplifier circuit 100B shown in FIG. 2B, and may include additional features not mentioned above. Consequently, repeated descriptions of the balanced amplifier circuit 100B1 described above with reference to FIG. 2B may be omitted for the sake of brevity.

For example, the balanced amplifier circuit 100B1 may include the first conversion circuit 111A that may output the plurality of signals S11 to S22, from an input signal IS having an input impedance Z0. The plurality of signals S11 to S22 may have a target input impedance Z1 and may have different phases. In the present disclosure, the first conversion circuit 111A shown in FIG. 3 may include and/or may be similar in many respects to the first conversion circuit 111 shown in FIG. 2B, and may include additional features not mentioned above. Consequently, repeated descriptions of the first conversion circuit 111A described above with reference to FIG. 2B may be omitted for the sake of brevity.

In the present disclosure, the target input impedance Z1 may be an impedance that minimizes signals reflected as the signals are transmitted to the first amplifier circuit AC1a and the second amplifier circuit AC2a. For example, the target input impedance Z1 may be approximately 50 Ω.

According to an embodiment, the first conversion circuit 111A may include a first transformer T1, a second transformer T2, a third transformer T3, a first capacitor C1, a second capacitor C2, and a first inductor L1.

For example, the first conversion circuit 111A may include the first transformer T1 connected between an input node IN and the first amplifier circuit AC1a.

In addition, the first conversion circuit 111A may include the second transformer T2 connected between an input resistor RI and the second amplifier circuit AC2a.

Further, the first conversion circuit 111A may include the first capacitor C1 connected between the input node IN and a ground.

In addition, the first conversion circuit 111A may include the first inductor L1 connected between a first node N1, which is between the input resistor RI and the second transformer T2, and the input node IN.

Further, the first conversion circuit 111A may include the second capacitor C2 connected between the first node N1 and the ground.

In addition, the first conversion circuit 111A may include the third transformer T3 connected between the second node N2 from which a first-first signal S11 is output and the third node N3 from which a first-second signal S12 is output and between a fourth node N4 from which a second-first signal S21 is output and a fifth node N5 from which a second-second signal S22 is output. In the present disclosure, the third transformer T3 may include an inductor connected between the second node N2 and the fourth node N4 and an inductor connected between the third node N3 and the fifth node N5.

Referring to FIG. 4, the first conversion circuit 511 may include a plurality of transmission lines (e.g., a first transmission line TL1, a second transmission line TL2, a third transmission line TL3, and a fourth transmission line TL4), a first matching circuit 521, and a second matching circuit 522.

For example, the first conversion circuit 511 may include the first transmission line TL1 connected between the input node IN and the input resistor RI. In addition, the first conversion circuit 511 may include the second transmission line TL2 connected between the input node IN and the first matching circuit 521. In addition, the first conversion circuit 511 may include the third transmission line TL3 connected between the input resistor RI and the second matching circuit 522. Further, the first conversion circuit 511 may include the fourth transmission line TL4 between the first matching circuit 521 and the second matching circuit 522.

The first conversion circuit 511 may generate an I signal I1 and a Q signal Q1, which have a phase difference of 90 degrees from each other, from a single-phase input signal IS via the plurality of first to fourth transmission lines TL1 to TL4. In the present disclosure, each of the I signal I1 and the Q signal Q1 may have a substantially similar and/or the same input impedance Z0 as the input signal IS.

Accordingly, at least a portion of the first conversion circuit 511, which includes the plurality of first to fourth transmission lines TL1 to TL4, may be referred to as a coupler circuit.

Further, the first conversion circuit 511 may include the first matching circuit 521 that outputs the first-first signal S11 and the first-second signal S12, each having the target input impedance Z1 and a differential relationship, from the I signal I1.

That is, the first matching circuit 521 may perform an impedance matching function to change an impedance of an input signal. In addition, the first matching circuit 521 may output the first-first signal S11 and the first-second signal S12 that are in the differential relationship, from the input signal I1.

Therefore, for example, the first matching circuit 521 may be referred to as an impedance matching circuit and/or a balun circuit.

In addition, the first conversion circuit 511 may include the second matching circuit 522 that outputs the second-first signal S21 and the second-second signal S22, each having the target input impedance Z1 and in a differential relationship, from the Q signal Q1.

That is, the second matching circuit 522 may perform an impedance matching function to change an impedance of an input signal. In addition, the second matching circuit 522 may output the second-first signal S21 and the second-second signal S22 that are in the differential relationship, from the input signal I1.

Therefore, for example, the second matching circuit 522 may be referred to as an impedance matching circuit and/or a balun circuit.

Referring to FIGS. 3 and 4, the first conversion circuit 111A shown in FIG. 3 and the first conversion circuit 511 shown in FIG. 4 may be equivalent.

For example, the first transmission line TL1 shown in FIG. 4 may include and/or may be similar in many respects to at least a portion of the first inductor L1, the first capacitor C1, and the second capacitor C2 shown in FIG. 3, and may include additional features not mentioned above. Consequently, repeated descriptions of the first transmission line TL1 described above with reference to FIG. 3 may be omitted for the sake of brevity.

For example, the first transmission line TL1 shown in FIG. 4 may be equivalently represented as two capacitors and one inductor connected between the two capacitors. That is, the first transmission line TL1 may be equivalently represented as one inductor and two capacitors, which may be connected in a pi(π) configuration.

In addition, at least a portion of the second transmission line TL2 and the first matching circuit 521 shown in FIG. 4 may include and/or may be similar in many respects to at least a portion of the first transformer T1 and the first capacitor C1 shown in FIG. 3, and may include additional features not mentioned above. Consequently, repeated descriptions of the second transmission line TL2 described above with reference to FIG. 3 may be omitted for the sake of brevity.***

For example, the second transmission line TL2 shown in FIG. 4 may be coupled to the first matching circuit 521 and may be equivalently represented as the first transformer T1 and capacitors connected in parallel across both ends of the first transformer T1. In the present disclosure, the capacitor connected to one end of the first transformer T1 may be referred to as the first capacitor C1 in FIG. 3. However, the capacitor connected to the other end of the first transformer T1 may be understood to be included in a first input parasitic capacitor IPC1 of the first amplifier circuit AC1a.

Therefore, the first capacitor C1 shown in FIG. 3 may be understood as a capacitor resulting from the combination of capacitors included in the equivalent circuit of the first transmission line TL1 and the second transmission line TL2.

In addition, at least a portion of the third transmission line TL3 and the second matching circuit 522 shown in FIG. 4 may include and/or may be similar in many respects to at least a portion of the second transformer T2 and the second capacitor C2 shown in FIG. 3, and may include additional features not mentioned above. Consequently, repeated descriptions of the third transmission line TL3 and the second matching circuit 522 described above with reference to FIG. 3 may be omitted for the sake of brevity.

For example, the third transmission line TL3 shown in FIG. 4 may be coupled to the second matching circuit 522 and may be equivalently represented as the second transformer T2 and capacitors connected in parallel across both ends of the second transformer T2. In the present disclosure, the capacitor connected to one end of the second transformer T2 may be the second capacitor C2 in FIG. 3. However, the capacitor connected to the other end of the second transformer T2 may be understood to be included in a second input parasitic capacitor IPC2 of the second amplifier circuit AC2a.

Therefore, the second capacitor C2 shown in FIG. 3 may be understood as a capacitor resulting from the combination of capacitors included in the equivalent circuit of the first transmission line TL1 and the third transmission line TL3.

In addition, at least a portion of the fourth transmission line TL4, the first matching circuit 521, and the second matching circuit 522 shown in FIG. 4 may be understood to be equivalent to the third transformer T3 shown in FIG. 3, and may include additional features not mentioned above. Consequently, repeated descriptions of the fourth transmission line TL4, the first matching circuit 521, and the second matching circuit 522 described above with reference to FIG. 3 may be omitted for the sake of brevity.

For example, the fourth transmission line TL4 shown in FIG. 4 may be coupled to the first matching circuit 521 and the second matching circuit 522 and may be equivalently represented as the third transformer T3 and capacitors connected in parallel across both ends of the third transformer T3. However, the capacitors connected to both ends of the third transformer T3 may be understood to be included in the first input parasitic capacitor IPC1 of the first amplifier circuit AC1a and the second input parasitic capacitor IPC2 of the second amplifier circuit AC2a, respectively.

As described above, the first conversion circuit 111A may perform operations of converting the impedance of the input signal IS, outputting the signals S11 and S12, which are in the differential relationship, from the single-phase input signal IS, and outputting the signals S11 and S21 which have the 90-degree phase difference with each other.

That is, the first conversion circuit 111A may perform an impedance matching function to output the plurality of signals S11 to S22 from the input signal IS having the input impedance Z0. Each of the plurality of signals S11 to S22 having the target input impedance Z1.

In addition, the first conversion circuit 111A may output signals that are in a differential relationship from the single-phase input signal IS. For example, the first conversion circuit 111A may output the first-first signal S11 and the first-second signal S12, which are in the differential relationship, from the single-phase input signal IS.

In addition, the first conversion circuit 111A may output signals that are orthogonal to each of the signals in the differential relationship. For example, the first conversion circuit 111A may output the second-first signal S21 that is orthogonal to the first-first signal S11. Further, the first conversion circuit 111A may output the second-second signal S22 that is orthogonal to the first-second signal S12.

Accordingly, the first conversion circuit 111A may be implemented with a relatively smaller area compared to a case (e.g., the first conversion circuit 511 of FIG. 4) where a circuit for impedance conversion, a circuit to generate differential signals, and a circuit to generate signals having the 90-degree phase difference are provided separately.

The balanced amplifier circuit 100B1, according to embodiments of the present disclosure, may reduce a circuit area that may be needed to output the plurality of signals S11 to S22 from the input signal IS, when compared to related amplifier circuits.

That is, through the above-described configurations, the balanced amplifier circuit 100B1, according to embodiments of the present disclosure, may reduce the area that may be needed to implement the electronic device 10, when compared to related amplifier circuits.

Referring to FIG. 3, the balanced amplifier circuit 100B1 may include the first amplifier circuit AC1a and the second amplifier circuit AC2a.

For example, the balanced amplifier circuit 100B1 may include the first amplifier circuit AC1a that amplifies the first-first signal S11 and the first-second signal S12.

The first amplifier circuit AC1a may include a first amplifier transistor ATR1 that amplifies the input signal (e.g. the first-first signal S11). In addition, the first amplifier circuit AC1a may include the first input parasitic capacitor IPC1 and a first output parasitic capacitor OPC1, which are connected in parallel to both ends of the first amplifier transistor ATR1.

The first amplifier circuit AC1a may amplify the first-first signal S11 and the first-second signal S12 by a specified gain. For example, the first amplifier circuit AC1a may amplify the first-first signal S11 through the first amplifier transistor ATR1 and may output the amplified first-first signal S11 as a first-third signal S13. In addition, the first amplifier circuit AC1a may amplify the first-second signal S12 through the first amplifier transistor ATR1 and may output the amplified first-second signal S12 as a first-fourth signal S14.

In addition, the balanced amplifier circuit 100B1 may include the second amplifier circuit AC2a that amplifies the second-first signal S21 and the second-second signal S22.

The second amplifier circuit AC2a may include a second amplifier transistor ATR2 that amplifies the input signal (e.g. the second-first signal S21). In addition, the second amplifier circuit AC2a may include the second input parasitic capacitor IPC2 and a second output parasitic capacitor OPC2, which are connected in parallel to both ends of the second amplifier transistor ATR2.

The second amplifier circuit AC2a may amplify the second-first signal S21 and the second-second signal S22 by a specified gain. For example, the second amplifier circuit AC2a may amplify the second-first signal S21 through the second amplifier transistor ATR2 and may output the amplified second-first signal S21 as a second-third signal S23. In addition, the second amplifier circuit AC2a may amplify the second-second signal S22 through the second amplifier transistor ATR2 and may output the amplified second-second signal S22 as a second-fourth signal S24.

In the present disclosure, the first amplifier circuit AC1a and the second amplifier circuit AC2a including the amplifier transistors ATR1 and ATR2, respectively, may be referred to as transistor amplifiers.

In addition, for example, the first amplifier circuit AC1a and the second amplifier circuit AC2a may amplify the signals (e.g., the first-first signal S11 and the first-second signal S12) that are in the differential relationship. Accordingly, each of the first amplifier circuit AC1a and the second amplifier circuit AC2a may be referred to as a differential amplifier.

Referring to FIG. 5, the balanced amplifier circuit 100B2, according to an embodiment, may include a first amplifier circuit AC1b and a second amplifier circuit AC2b, each including a plurality of amplifiers.

For example, the first amplifier circuit AC1b may include a first amplifier A1 that amplifies the first-first signal S11. In addition, the first amplifier circuit AC1b may include a second amplifier A2 that amplifies the first-second signal S12.

Further, the second amplifier circuit AC2b may include a third amplifier A3 that amplifies the second-first signal S21. The second amplifier circuit AC2b may include a fourth amplifier A4 that amplifies the second-second signal S22.

In the embodiment where each of the first amplifier circuit AC1b and the second amplifier circuit AC2b is implemented with a plurality of amplifiers, a first conversion circuit 111A1 and a second conversion circuit 112A1 may further include equivalent capacitors EC1, EC2, EC3, and EC4.

For example, when the first amplifier circuit AC1b is implemented with the plural amplifiers A1 and A2, the first conversion circuit 111A1 may include a first equivalent capacitor EC1 connected between a second node N2 and a third node N3. In the present disclosure, the first equivalent capacitor EC1 may be understood as a capacitor obtained by the combination of capacitors included in the equivalent circuit of the second transmission line TL2 and the fourth transmission line TL4 shown in FIG. 4.

Additionally, when the second amplifier circuit AC2b is implemented with the plural amplifiers A3 and A4, the first conversion circuit 111A1 may include a second equivalent capacitor EC2 connected between a fourth node N4 and a fifth node N5. In the present disclosure, the second equivalent capacitor EC2 may be understood as a capacitor obtained by the combination of capacitors included in the equivalent circuit of the third transmission line TL3 and the fourth transmission line TL4 shown in FIG. 4.

Accordingly, the first conversion circuit 111A1 shown in FIG. 5 may be understood to include the first equivalent capacitor EC1 and the second equivalent capacitor EC2 in addition to the configuration of the first conversion circuit 111A shown in FIG. 3.

When the first amplifier circuit AC1b is implemented with the plural amplifiers A1 and A2, the second conversion circuit 112A1 may include a third equivalent capacitor EC3 connected between a sixth node N6 and a seventh node N7.

When the second amplifier circuit AC2b is implemented with the plural amplifiers A3 and A4, the second conversion circuit 112A1 may include a fourth equivalent capacitor EC4 connected between an eighth node N8 and a ninth node N9.

Accordingly, the second conversion circuit 112A1 shown in FIG. 5 may be understood to include the third equivalent capacitor EC3 and the fourth equivalent capacitor EC4 in addition to the configuration of the second conversion circuit 112A shown in FIG. 3.

However, for convenience of explanation, in the following description, it is assumed that each of the amplifier circuits AC1a and AC2a included in the balanced amplifier circuit 100B1 is a transistor amplifier including an amplifier transistor.

In addition, referring to FIG. 3, the balanced amplifier circuit 100B1 may include the second conversion circuit 112A that outputs an output signal OS having an output impedance Z3 from the first-third to second-fourth signals S13 to S24, each having a target output impedance Z2 and the 90-degree phase difference with respect to one another.

In the present disclosure, the second conversion circuit 112A shown in FIG. 3 may include and/or may be similar in many respects to the second conversion circuit 112 shown in FIG. 2B, and may include additional features not mentioned above. Consequently, repeated descriptions of the second conversion circuit 112A described above with reference to FIG. 2B may be omitted for the sake of brevity.

The second conversion circuit 112A may include a fourth transformer T4, a fifth transformer T5, a sixth transformer T6, a third capacitor C3, a fourth capacitor C4, and a second inductor L2.

For example, the second conversion circuit 112A may include the fourth transformer T4 connected between the first amplifier circuit AC1a and an output resistor RO. In addition, the second conversion circuit 112A may include the fifth transformer T5 connected between the second amplifier circuit AC2a and an output node ON.

In addition, the second conversion circuit 112A may include the sixth transformer T6 connected between a sixth node N6 from which the first-third signal S13 is output and a seventh node N7 from which the first-fourth signal S14 is output and between an eighth node N8 from which the second-third signal S23 is output and a ninth node N9 from which the second-fourth signal S24 is output. In the present disclosure, the sixth transformer T6 may include an inductor connected between the sixth node N6 and the eighth node N8 and an inductor connected between the seventh node N7 and the ninth node N9.

Further, the second conversion circuit 112A may include the third capacitor C3 connected between a tenth node N10, which is disposed between the fourth transformer T4 and the output resistor RO, and the ground. The second conversion circuit 112A may include the second inductor L2 connected between the output node ON and the tenth node N10. In addition, the second conversion circuit 112A may include the fourth capacitor C4 connected between the output node ON and the ground.

The second conversion circuit 112A may perform an impedance matching function to output the output signal OS having the output impedance Z3 from the first-third to second-fourth signals S13 to S24, each having the target input impedance Z2.

In addition, the second conversion circuit 112A may output the single-phase output signal OS from the signals that are in the differential relationship and from the signals having the 90-degree phase difference with each of the differential signals.

That is, the second conversion circuit 112A may perform an operation of converting the impedance of the signal input thereto and may output the single-phase signal from the signals having phase differences from each other.

Accordingly, the balanced amplifier circuit 100B1, according to the present disclosure, may be implemented in a relatively smaller area compared to a case where a circuit for impedance conversion, a circuit to generate differential signals, and a circuit to generate signals having the 90-degree phase difference with each of the differential signals are provided separately.

That is, through the above-described structures, the balanced amplifier circuit 100B1, according to the present disclosure, may reduce the area that may be needed to implement the electronic device 10, when compared to related amplifier circuits.

In addition, the balanced amplifier circuit 100B1, according to the present disclosure, may include a relatively smaller number of passive elements compared to a case where the circuit the impedance conversion and the circuit to generate the single-phase signal from the signals in the differential relationship and the signals having the 90-degree phase difference with the signals in the differential relationship are provided separately.

Accordingly, the balanced amplifier circuit 100B1, according to the present disclosure, may reduce power consumption due to the passive elements, when compared to related amplifier circuits. Further, the balanced amplifier circuit 100B1 may improve output power and gain, when compared to related amplifier circuits.

In addition, referring to the configurations described above, the balanced amplifier circuit 100B1 may amplify the signals having the 90-degree phase difference with each other using different amplifier circuits AC1a and AC2a.

Furthermore, the balanced amplifier circuit 100B1 may output the single-phase output signal OS having the output impedance Z3 from the first-third to second-fourth signals S13 to S24 that are output through the different amplifier circuits AC1a and AC2a.

Therefore, the electronic device 10 (or the balanced amplifier circuit 100B1), according to the present disclosure, may improve the output power, when compared to related amplifier circuits.

In addition, the electronic device 10 (or the balanced amplifier circuit 100B1), according to the present disclosure, may operate with less sensitivity to changes in load impedance by separately amplifying the signals having the 90-degree phase difference with each other.

That is, the balanced amplifier circuit 100B1, according to the present disclosure, may improve the performance of the RF signal transmission operation of the electronic device 10, when compared to related amplifier circuits.

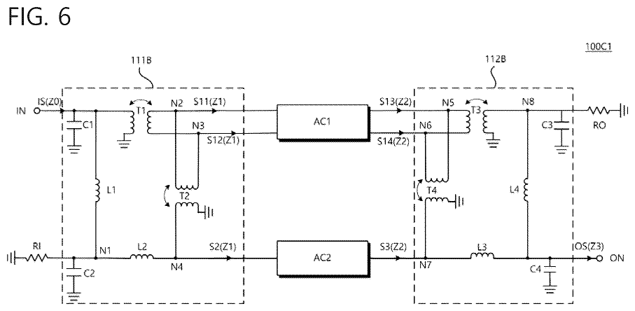

FIG. 6 is a circuit diagram showing a balanced amplifier circuit including a first conversion circuit, according to an embodiment of the present disclosure.

Referring to FIG. 6, the balanced amplifier circuit 100C1 may include a first conversion circuit 111B, a first amplifier circuit AC1, a second amplifier circuit AC2, and a second conversion circuit 112B.

The balanced amplifier circuit 100C1 shown in FIG. 6 may include and/or may be similar in many respects to the balanced amplifier circuit 100B shown in FIG. 2B, and may include additional features not mentioned above. Consequently, repeated descriptions of the balanced amplifier circuit 100C1 described above with reference to FIG. 2B may be omitted for the sake of brevity.

The balanced amplifier circuit 100C1 may include the first conversion circuit 111B that outputs a plurality of signals S11, S12, and S2, each having a target input impedance Z1 and different phases, from an input signal IS having an input impedance ZO. In the present disclosure, the first conversion circuit 111B shown in FIG. 6 may include and/or may be similar in many respects to the first conversion circuit 111 shown in FIG. 2B, and may include additional features not mentioned above. Consequently, repeated descriptions of the first conversion circuit 111B described above with reference to FIG. 2B may be omitted for the sake of brevity.

In the present disclosure, a first-first signal S11 and a first-second signal S12 may be in a differential relationship with each other. In addition, the first-first signal S11 and a second signal S2 may have a phase difference of 90 degrees with each other.

According to an embodiment the first conversion circuit 111B may include a first transformer T1, a second transformer T2, a first inductor L1, a second inductor L2, a first capacitor C1, and a second capacitor C2.

For example, the first conversion circuit 111B may include the first transformer T1 connected between an input node IN and the first amplifier circuit AC1. In addition, the first conversion circuit 111B may include the first capacitor C1 connected between the input node IN and a ground.

In addition, the first conversion circuit 111B may include the first inductor L1 connected between the input node IN and a first node N1. The first conversion circuit 111B may include the second capacitor C2 connected between the first node N1 and the ground.

Further, the first conversion circuit 111B may include the second transformer T2 connected between a fourth node N4 from which the second signal S2 is output and a second node N2 from which the first-first signal S11 is output and between the fourth node N4 and a third node N3 from which the first-second signal S12 is output. For example, the second transformer T2 may include an inductor connected between the second node N2 and the third node N3 and an inductor connected between the fourth node N4 and the ground.

The first conversion circuit 111B may include the second inductor L2 connected between the first node N1 and the fourth node N4.

The first conversion circuit 111B may perform operations of converting the impedance of the input signal IS and outputting the signals S11, S12, and S2 having different phases from each other from the single-phase input signal IS.

That is, the first conversion circuit 111B may perform an impedance matching function to output the signals S11, S12, and S2, each having the target input impedance Z1, from the input signal IS having the input impedance ZO.

The first conversion circuit 111B may output the signals in the differential relationship from the single-phase input signal IS. For example, the first conversion circuit 111B may output the first-first signal S11 and the first-second signal S12, which are in the differential relationship, from the single-phase input signal IS.

The first conversion circuit 111B may output signals having the 90-degree phase difference with each other. For example, the first conversion circuit 111B may output the second signal S2 that is orthogonal to the first-first signal S11.

Therefore, the first conversion circuit 111B may be implemented with a relatively smaller area compared to a case where a circuit for impedance conversion, a circuit to generate the differential signals, and a circuit to generate the signals having the 90-degree phase difference are provided separately.

The balanced amplifier circuit 100C1, according to the present disclosure, may reduce a circuit area that may be needed to output the signals S11, S12, and S2 from the input signal IS, when compared to related amplifier circuits.

That is, according to the above-mentioned configurations, the balanced amplifier circuit 100C1 may reduce the area that may be needed to implement the electronic device 10, when compared to related amplifier circuits.

The balanced amplifier circuit 100C1 may include the first amplifier circuit AC1 and the second amplifier circuit AC2.

For example, the balanced amplifier circuit 100C1 may include the first amplifier circuit AC1 that amplifies the first-first signal S11 and the first-second signal S12.

The first amplifier circuit AC1 may amplify the first-first signal S11 and the first-second signal S12 by a specified gain. For example, the first amplifier circuit AC1 may amplify the first-first signal S11 and may output the amplified first-first signal S11 as a first-third signal S13. In addition, the first amplifier circuit AC1 may amplify the first-second signal S12 and may output the amplified first-second signal S12 as a first-fourth signal S14.

In addition, the balanced amplifier circuit 100C1 may include the second amplifier circuit AC2 that amplifies the second signal S2.

The second amplifier circuit AC2 may amplify the second signal S2 by a specified gain. For example, the second amplifier circuit AC2 may amplify the second signal S2 and may output the amplified second signal S2 as a third signal S3.

In the present disclosure, the first amplifier circuit AC1 may amplify the signals that are in the differential relationship (e.g., the first-first signal S11 and the first-second signal S12). Therefore, the first amplifier circuit AC1 may be referred to as a differential amplifier. In addition, for example, the second amplifier circuit AC2 may be understood as an amplifier that amplifies a single-phase signal.

In addition, the balanced amplifier circuit 100C1 may include the second conversion circuit 112B that outputs an output signal OS having an output impedance Z3 from the first-third signal S13, the first-fourth signal S14, and the third signal S3, each having a target output impedance Z2 and a 90-degree phase difference with respect to one another.

In the present disclosure, the second conversion circuit 112B shown in FIG. 6 may include and/or may be similar in many respects to the second conversion circuit 112 shown in FIG. 2B, and may include additional features not mentioned above. Consequently, repeated descriptions of the second conversion circuit 112B described above with reference to FIG. 2B may be omitted for the sake of brevity.

The second conversion circuit 112B may include a third transformer T3, a fourth transformer T4, a third capacitor C3, a fourth capacitor C4, a third inductor L3, and a fourth inductor L4.

For example, the second conversion circuit 112B may include the third transformer T3 connected between the first amplifier circuit AC1 and an output resistor RO.

In addition, the second conversion circuit 112B may include the fourth transformer T4 connected between a fifth node N5 from which the first-third signal S13 is output and a seventh node N7 from which the third signal S3 is output and between a sixth node N6 from which the first-fourth signal S14 is output and the seventh node N7 from which the third signal S3 is output. That is, the fourth transformer T4 may include an inductor connected between the fifth node N5 and the sixth node N6 and an inductor connected between the seventh node N7 and the ground.

Further, the second conversion circuit 112B may include the third inductor L3 connected between the seventh node N7 and an output node ON. The second conversion circuit 112B may include the third capacitor C3 connected between an eighth node N8, which is between the third transformer T3 and the output resistor RO, and the ground. The second conversion circuit 112B may include the fourth inductor L4 connected between the output node ON and the eighth node N8. In addition, the second conversion circuit 112B may include the fourth capacitor C4 connected between the output node ON and the ground.

The second conversion circuit 112B may perform an impedance matching function to output the output signal OS having the output impedance Z3 from the first-third signal S13, the first-fourth signal S14, and the third signal S3, each having the target output impedance Z2.

In addition, the second conversion circuit 112B may output a single-phase output signal OS from signals that are in a differential relationship and signals that have a 90-degree phase difference with each other. For example, the second conversion circuit 112B may output the single-phase output signal OS from the first-third signal S13 and the first-fourth signal S14, which are in the differential relationship, and the third signal S3, which has the 90-degree phase difference with the first-third signal S13.

That is, the second conversion circuit 112B may perform operations of converting the impedance of the signal input thereto and outputting a single-phase signal from the signals having the phase difference with each other.

Therefore, the balanced amplifier circuit 100C1, according to the present disclosure, may be implemented with a relatively smaller area compared to a case where a circuit for impedance conversion and a circuit to generate the single-phase signal from the signals in the differential relationship and the signals having the 90-degree phase difference are provided separately.

That is, according to the above-described configurations, the balanced amplifier circuit 100C1 may reduce the area that may be needed to implement the electronic device 10, when compared to related amplifier circuits.

In addition, the balanced amplifier circuit 100C1, according to the present disclosure, may include a relatively smaller number of passive elements compared to a case where the circuit for impedance conversion and the circuit to generate the single-phase signal from the signals in the differential relationship and the signals having the 90-degree phase difference are provided separately.

Accordingly, the balanced amplifier circuit 100C1, according to the present disclosure, may reduce power consumption due to the passive elements, when compared to related amplifier circuits. Further, the balanced amplifier circuit 100C1 may improve output power and gain, when compared to related amplifier circuits.

In addition, referring to the configurations described above, the balanced amplifier circuit 100C1 may amplify the signals having the 90-degree phase difference with each other using different first and second amplifier circuits AC1 and AC2.

Furthermore, the balanced amplifier circuit 100C1 may output the single-phase output signal OS having the output impedance Z3 from the first-third signal S13, the first-fourth signal S14, and the third signal S3 output through the first and second different first and second amplifier circuits AC1 and AC2.

Therefore, the electronic device 10 (or the balanced amplifier circuit 100C1), according to the present disclosure, may improve the output power, when compared to related amplifier circuits.

In addition, the electronic device 10 (or the balanced amplifier circuit 100C1), according to the present disclosure, may operate with less sensitivity to changes in load impedance by separately amplifying the signals having the 90-degree phase difference with each other.

That is, the balanced amplifier circuit 100C1, according to the present disclosure, may improve the performance of the RF signal transmission operation of the electronic device 10, when compared to related amplifier circuits.

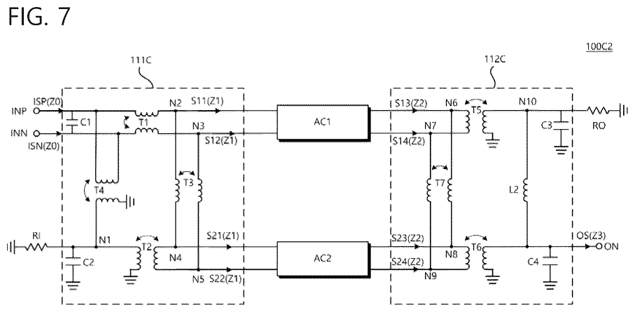

FIG. 7 is a circuit diagram showing a balanced amplifier circuit including a first conversion circuit, according to an embodiment of the present disclosure.

Referring to FIG. 7, the balanced amplifier circuit 100C2 may include a first conversion circuit 111C, a first amplifier circuit AC1, a second amplifier circuit AC2, and a second conversion circuit 112C.

The balanced amplifier circuit 100C2 shown in FIG. 7 may include and/or may be similar in many respects to the balanced amplifier circuit 100B shown in FIG. 2B, and may include additional features not mentioned above. Consequently, repeated descriptions of the balanced amplifier circuit 100C2 described above with reference to FIG. 2B may be omitted for the sake of brevity

The balanced amplifier circuit 100C2 may receive a first input signal ISP having an input impedance ZO through a first input node INP. In addition, the balanced amplifier circuit 100C2 may receive a second input signal ISN having the input impedance ZO through a second input node INN. In the present disclosure, the first input signal ISP and the second input signal ISN may have a differential relationship with each other.

The balanced amplifier circuit 100C2 may include the first conversion circuit 111C that may output the plurality of signals S11 to S22, from the first and second input signals ISP and ISN. Each of the first and second input signals ISP and ISB may have the input impedance ZO. Each of the plurality of signals S11 to S22 may have a target input impedance Z1 and different phases. In the present disclosure, the first conversion circuit 111C shown in FIG. 7 may include and/or may be similar in many respects to the first conversion circuit 111 shown in FIG. 2B, and may include additional features not mentioned above. Consequently, repeated descriptions of the first conversion circuit 111C described above with reference to FIG. 2B may be omitted for the sake of brevity.

In the present disclosure, for example, a first-first signal S11 and a first-second signal S12 may be in a differential relationship with each other. In addition, a second-first signal S21 and a second-second signal S22 may be in the differential relationship with each other. Further, the first-first signal S11 and the second-first signal S21 may have a 90-degree phase difference. The first-second signal S12 and the second-second signal S22 may have a 90-degree phase difference.

The first conversion circuit 111C may include a first transformer T1, a second transformer T2, a third transformer T3, a fourth transformer T4, a first capacitor C1, and a second capacitor C2.

That is, the first conversion circuit 111C may include the first transformer T1 connected between the first amplifier circuit AC1 and the first input node INP and between the first amplifier circuit AC1 and the second input node INN. In addition, the first conversion circuit 111C may include the first capacitor C1 connected between the first input node INP and the second input node INN.

In addition, the first conversion circuit 111C may include the second transformer T2 connected between an input resistor RI and the second amplifier circuit AC2.

Furthermore, the first conversion circuit 111C may include the second capacitor C2 connected between a first node N1, which is between the input resistor RI and the second transformer T2, and a ground.

The first conversion circuit 111C may include the third transformer T3 connected between a second node N2 where the first-first signal S11 is output and a fourth node N4 where the second-first signal S21 is output and between a third node N3 where the first-second signal S12 is output and a fifth node N5 where the second-second signal S22 is output. In the present disclosure, the third transformer T3 may include an inductor connected between the second node N2 and the fourth node N4 and an inductor connected between the third node N3 and the fifth node N5.

In addition, the first conversion circuit 111C may include the fourth transformer T4 connected between the first input node INP and the first node N1 and between the second input node INN and the first node N1. In the present disclosure, the fourth transformer T4 may include an inductor connected between the first input node INP and the second input node INN and an inductor connected between the first node N1 and the ground.

The first conversion circuit 111C may perform operations of converting the impedance of the first and second input signals ISP and ISN, outputting the first-first and first-second signals S11 and S12, which are in a differential relationship, from the first and second input signals ISP and ISN, and outputting the first-first and second-first signals S11 and S21 having a 90-degree phase difference with each other.

That is, the first conversion circuit 111C may perform an impedance matching function to output the plurality of signals S11 to S22, from the first and second input signals ISP and ISN. Each of the first and second input signals ISP and ISN may have the input impedance ZO. Each of the plurality of signals S11 to S22 may have the target input impedance Z1.

The first conversion circuit 111C may output the signals that are in the differential relationship. For example, the first conversion circuit 111C may output the first-first signal S11 and the second-first signal S21, which are in the differential relationship.

The first conversion circuit 111C may output the signals having the 90-degree phase difference with each other. For example, the first conversion circuit 111C may output the second-first signal S21 having the 90-degree phase difference with the first-first signal S11.

Therefore, the first conversion circuit 111C may be implemented with a relatively smaller area compared to a case where a circuit for impedance conversion, a circuit to generate the signals in the differential relationship, and a circuit to generate the signals having the 90-degree phase difference with each other are provided separately.

The balanced amplifier circuit 100C2, according to the present disclosure, may reduce a circuit area that may be needed to output the plurality of signals S11 to S22 from the first and second input signals ISP and ISN, when compared to related amplifier circuits.

That is, according to the above-described configurations, the balanced amplifier circuit 100C2 may reduce the area that may be needed to implement the electronic device 10, when compared to related amplifier circuits.

In addition, the balanced amplifier circuit 100C2 may include the first amplifier circuit AC1 and the second amplifier circuit AC2. In the present disclosure, the first amplifier circuit AC1 may be understood to have a substantially similar and/or the same configuration as the first amplifier circuit AC1a shown in FIG. 3, and may include additional features not mentioned above. Further, the second amplifier circuit AC2 may be understood to have a substantially similar and/or the same configuration as the second amplifier circuit AC2a shown in FIG. 3, and may include additional features not mentioned above. Consequently, repeated descriptions of the balanced amplifier circuit 100C2 described above with reference to FIG. 3 may be omitted for the sake of brevity.

In addition, the balanced amplifier circuit 100C2 may include the second conversion circuit 112C that outputs an output signal OS having an output impedance Z3 from a plurality of first-third to second-fourth signals S13 to S24, each having a target output impedance Z2 and a 90-degree phase difference with respect to one another In the present disclosure, the second conversion circuit 112C shown in FIG. 7 may include and/or may be similar in many respects to the second conversion circuit 112 shown in FIG. 2B, and may include additional features not mentioned above. Consequently, repeated descriptions of the second conversion circuit 112C described above with reference to FIG. 2B may be omitted for the sake of brevity.

The second conversion circuit 112C may include a fifth transformer T5, a sixth transformer T6, a seventh transformer T7, a third capacitor C3, a fourth capacitor C4, and a second inductor L2.

For example, the second conversion circuit 112C may include the fifth transformer T5 connected between the first amplifier circuit AC1 and an output resistor RO. In addition, the second conversion circuit 112C may include the sixth transformer T6 connected between the second amplifier circuit AC2 and an output node ON.

In addition, the second conversion circuit 112C may include the seventh transformer T7 connected between a sixth node N6 from which a first-third signal S13 is output and an eighth node N8 from which a second-third signal S23 is output and between a seventh node N7 from which a first-fourth signal S14 is output and a ninth node N9 from which a second-fourth signal S24 is output. In the present disclosure, the seventh transformer T7 may include an inductor connected between the sixth node N6 and the eighth node N8 and an inductor connected between the seventh node N7 and the ninth node N9.

The second conversion circuit 112C may include the third capacitor C3 connected between a tenth node N10, which is between the fifth transformer T5 and the output resistor RO, and the ground. In addition, the second conversion circuit 112C may include the fourth capacitor C4 connected between the output node ON and the ground.

The second conversion circuit 112C may include the second inductor L2 connected between the tenth node N10 and the output node ON.

The second conversion circuit 112C may perform an impedance matching function to output the output signal OS having the output impedance Z3 from the first-third to second-fourth signals S13 to S24, each having the target output impedance Z2.

In addition, the second conversion circuit 112C may output a single-phase output signal OS from the signals that are in the differential relationship and the signals that have the 90-degree phase difference with each other. For example, the second conversion circuit 112C may output the single-phase output signal OS from the first-third signal S13 and the first-fourth signal S14, which are in the differential relationship, the second-third signal S23, which has the 90-degree phase difference with the first-third signal S13, and the second-fourth signal S24, which has the 90-degree phase difference with the first-fourth signal S14.

That is, the second conversion circuit 112C may perform operations of converting the impedance of the input signal and outputting the single-phase signal from the signals having phase differences with each other.

Therefore, the balanced amplifier circuit 100C2, according to the present disclosure, may be implemented with a relatively smaller area compared to a case where ta circuit for impedance conversion and a circuit to generate the single-phase signal from the signals in the differential relationship and the signals having the 90-degree phase difference with each other are provided separately.

That is, according to the above-described configurations, the balanced amplifier circuit 100C2 may reduce the area that may be needed to implement the electronic device 10, when compared to related amplifier circuits.

In addition, the balanced amplifier circuit 100C2, according to the present disclosure, may include a relatively smaller number of passive elements compared to a case where a circuit for impedance conversion, a circuit to generate the single-phase signal from the signals in the differential relationship, and a circuit to generate the signals having the 90-degree phase difference with respect to each of the signals in the differential relationship are provided separately.

Therefore, the balanced amplifier circuit 100C2, according to the present disclosure, may reduce power consumption due to the passive elements, when compared to related amplifier circuits. In addition, the balanced amplifier circuit 100C2 may improve output power and gain, when compared to related amplifier circuits.

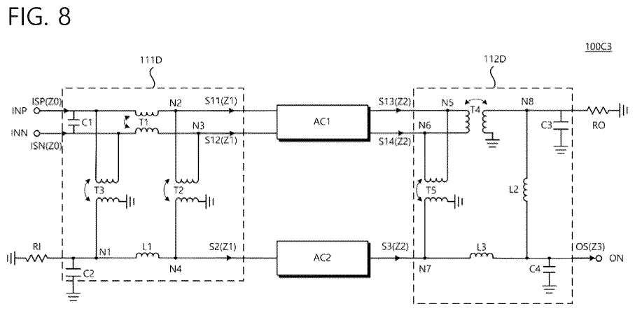

FIG. 8 is a circuit diagram showing a balanced amplifier circuit including a first conversion circuit, according to an embodiment of the present disclosure.

Referring to FIG. 8, the balanced amplifier circuit 100C3 may include a first conversion circuit 111D, a first amplifier circuit AC1, a second amplifier circuit AC2, and a second conversion circuit 112D.

The balanced amplifier circuit 100C3 shown in FIG. 8 may include and/or may be similar in many respects to the balanced amplifier circuit 100B shown in FIG. 2B, and may include additional features not mentioned above. Consequently, repeated descriptions of the balanced amplifier circuit 100C3 described above with reference to FIG. 2B may be omitted for the sake of brevity.

The balanced amplifier circuit 100C3 may receive a first input signal ISP having an input impedance ZO through a first input node INP. The balanced amplifier circuit 100C3 may receive a second input signal ISN having the input impedance ZO through a second input node INN. In the present disclosure, the first input signal ISP and the second input signal ISN may have a differential relationship with each other.

The balanced amplifier circuit 100C3 may include the first conversion circuit 111D that outputs a plurality of signals S11, S12, and S2, each having a target input impedance Z1 and different phases, from the first and second input signals ISP and ISN, each having the input impedance ZO. In the present disclosure, the first conversion circuit 111D shown in FIG. 8 may include and/or may be similar in many respects to the first conversion circuit 111 shown in FIG. 2B, and may include additional features not mentioned above. Consequently, repeated descriptions of the first conversion circuit 111D described above with reference to FIG. 2B may be omitted for the sake of brevity.

A first-first signal S11 and a first-second signal S12 may be in the differential relationship. In addition, the first-first signal S11 and a second signal S2 may have the 90-degree phase difference with respect to each other.

The first conversion circuit 111D may include a first transformer T1, a second transformer T2, a third transformer T3, a first inductor L1, a first capacitor C1, and a second capacitor C2.

For example, the first conversion circuit 111D may include the first transformer T1 connected between the first input node INP and the first amplifier circuit AC1 and between the second input node INN and the first amplifier circuit AC1. In addition, the first conversion circuit 111D may include the first capacitor C1 connected between the first input node INP and the second input node INN.

The first conversion circuit 111D may include the first inductor L1 connected between an input resistor RI and the second amplifier circuit AC2. In addition, the first conversion circuit 111D may include the second capacitor C2 connected between a first node N1, which is between the input resistor RI and the first inductor L1, and a ground.

In addition, the first conversion circuit 111D may include the second transformer T2 connected between a fourth node N4 from which the second signal S2 is output and a second node N2 from which the first-first signal S11 is output and between the fourth node N4 from which the second signal S2 is output and a third node N3 from which the first-second signal S12 is output. In the present disclosure, the second transformer T2 may include an inductor connected between the second node N2 and the third node N3 and an inductor connected between the fourth node N4 and the ground.

The first conversion circuit 111D may include the third transformer T3 connected between the first input node INP and the first node N1 and between the second input node INN and the first node N1. In the present disclosure, the third transformer T3 may include an inductor connected between the first input node INP and the second input node INN and an inductor connected between the first node N1 and the ground.

The first conversion circuit 111D may perform operations of converting the impedance of the first and second input signals ISP and ISN and outputting the signals S11, S12, and S2, which have different phases, from the first and second input signals ISP and ISN in the differential relationship.

For example, the first conversion circuit 111D may perform an impedance matching function to output the signals S11, S12, and S2, each having the target input impedance Z1, from the first and second input signals ISP and ISN, each having the input impedance ZO.

In addition, the first conversion circuit 111D may output the signals S11, S12, and S2, which have different phases, from the first and second input signals ISP and ISN in the differential relationship. For example, the first conversion circuit 111D may output the first-first signal S11 and the first-second signal S12, which are in the differential relationship with each other. Also, for example, the first conversion circuit 111D may output the second signal S2 having the 90-degree phase difference with the first-first signal S11.

Therefore, the first conversion circuit 111D may be implemented with a relatively smaller area compared to a case where a circuit for impedance conversion, a circuit to generate the signals in the differential relationship, and a circuit to generate the signals having the 90-degree phase difference are provided separately.

The balanced amplifier circuit 100C3, according to the present disclosure, may reduce a circuit area that may be needed to output the signals S11, S12, and S2 from the first and second input signals ISP and ISN, when compared to related amplifier circuits.

That is, according to the above-described configurations, the balanced amplifier circuit 100C3 may reduce an area that may be needed to implement the electronic device 10, when compared to related amplifier circuits.

The balanced amplifier circuit 100C3 may include the first amplifier circuit AC1 and the second amplifier circuit AC2.

For example, the balanced amplifier circuit 100C3 may include the first amplifier circuit AC1 that amplifies the first-first signal S11 and the first-second signal S12.

The first amplifier circuit AC1 may amplify the first-first signal S11 and the first-second signal S12 by a specified gain. For example, the first amplifier circuit AC1 may amplify the first-first signal S11 and may output the amplified first-first signal S11 as a first-third signal S13. In addition, the first amplifier circuit AC1 may amplify the first-second signal S12 and may output the amplified first-second signal S12 as a first-fourth signal S14.

The balanced amplifier circuit 100C3 may include the second amplifier circuit AC2 that amplifies the second signal S2.

The second amplifier circuit AC2 may amplify the second signal S2 by a specified gain. For example, the second amplifier circuit AC2 may amplify the second signal S2 and may output the amplified second signal S2 as a third signal S3.

In the present disclosure, the first amplifier circuit AC1 may amplify the signals that are in the differential relationship (e.g., the first-first signal S11 and the first-second signal S12). Therefore, the first amplifier circuit AC1 may be referred to as a differential amplifier. In addition, the second amplifier circuit AC2 may be understood as an amplifier that amplifies a single-phase signal.

In addition, the balanced amplifier circuit 100C3 may include the second conversion circuit 112D that outputs an output signal OS having an output impedance Z3 from the first-third signal S13, the first-fourth signal S14, and the third signal S3, each having a target output impedance Z2 and a 90-degree phase difference with respect to one another.

In the present disclosure, the second conversion circuit 112D shown in FIG. 8 may include and/or may be similar in many respects to the second conversion circuit 112 shown in FIG. 2B, and may include additional features not mentioned above. Consequently, repeated descriptions of the second conversion circuit 112D described above with reference to FIG. 2B may be omitted for the sake of brevity.

In an embodiment, the second conversion circuit 112D may include a fourth transformer T4, a fifth transformer T5, a third capacitor C3, a fourth capacitor C4, a second inductor L2, and a third inductor L3.

That is, the second conversion circuit 112D may include the fourth transformer T4 connected between the first amplifier circuit AC1 and an output resistor RO.

In addition, the second conversion circuit 112D may include the fifth transformer T5 connected between a fifth node N5 from which the first-third signal S13 is output and a seventh node N7 from which the third signal S3 is output and between the sixth node N6 from which the first-fourth signal S14 is output and the seventh node N7. In the present disclosure, the fifth transformer T5 may include an inductor connected between the fifth node N5 and the sixth node N6 and an inductor connected between the seventh node N7 and the ground.

The second conversion circuit 112D may include the third capacitor C3 connected between an eighth node N8, which is between the fourth transformer T4 and the output resistor RO, and the ground. In addition, the second conversion circuit 112D may include the fourth capacitor C4 connected between an output node ON and the ground.

The second conversion circuit 112D may include the second inductor L2 connected between the output node ON and the eighth node N8. In addition, the second conversion circuit 112D may include the third inductor L3 connected between the seventh node N7 and the output node ON.

The second conversion circuit 112D may perform an impedance matching function to output the output signal OS having the output impedance Z3 from the first-third signal S13, the first-fourth signal S14, and the third signal S3, each having the target output impedance Z2.

The second conversion circuit 112D may output the single-phase output signal OS from the signals that are in the differential relationship and the signals that have the 90-degree phase difference with each other. For example, the second conversion circuit 112D may output the single-phase output signal OS from the first-third signal S13 and the first-fourth signal S14, which are in the differential relationship, and the third signal S3, which has the 90-degree phase difference with the first-third signal S13.

That is, the second conversion circuit 112D may perform operations of converting the impedance of the input signals and outputting the single-phase signal from the signals having a phase difference with each other.

Therefore, the balanced amplifier circuit 100C3, according to the present disclosure, may be implemented with a relatively smaller area compared to a case where a circuit for impedance conversion and a circuit to generate the single-phase signal from the signals in the differential relationship and the signals having the 90-degree phase difference with each other are provided separately.

That is, according to the above-described configurations, the balanced amplifier circuit 100C3 may reduce the area that may be needed to implement the electronic device 10, when compared to related amplifier circuits.

In addition, the balanced amplifier circuit 100C3, according to the present disclosure, may include a relatively smaller number of passive elements compared to a case where a circuit for impedance conversion, a circuit to generate the single-phase signal from the signals in the differential relationship, and a circuit to generate the signals having the 90-degree phase difference with each other are provided separately.

Therefore, the balanced amplifier circuit 100C3, according to the present disclosure, may reduce power consumption due to the passive elements, when compared to related amplifier circuits. Further, the balanced amplifier circuit 100C3 may improve output power and gain, when compared to related amplifier circuits.

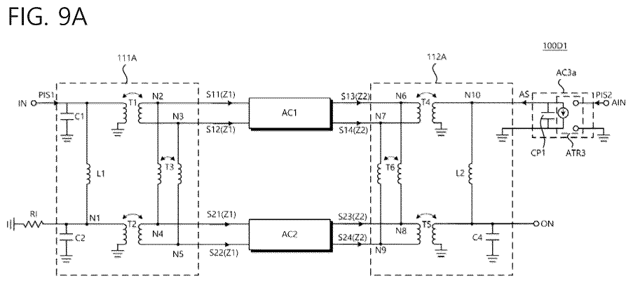

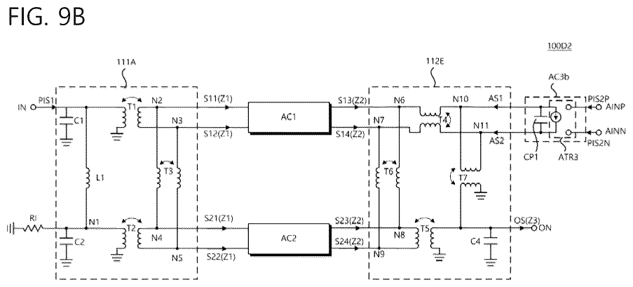

FIG. 9A is a circuit diagram showing a balanced amplifier circuit further including a third amplifier circuit, according to an embodiment of the present disclosure. FIG. 9B is a circuit diagram showing a balanced amplifier circuit further including a third amplifier circuit that receives a differential signal, according to an embodiment of the present disclosure.

Referring to FIGS. 9A and 9B, the balanced amplifier circuits 100D1 and 100D2 may include the third amplifier circuits AC3a and AC3b, respectively.

Referring to FIG. 9A, the balanced amplifier circuit 100D1 may include a first conversion circuit 111A, a first amplifier circuit AC1, a second amplifier circuit AC2, and a second conversion circuit 112A.

The balanced amplifier circuit 100D1 shown in FIG. 9A may include and/or may be similar in many respects to the balanced amplifier circuit 100B shown in FIG. 2B, and may include additional features not mentioned above. For example, the balanced amplifier circuit 100D1 may omit (not include) the output resistor RO. Consequently, repeated descriptions of the balanced amplifier circuit 100D1 described above with reference to FIG. 2B may be omitted for the sake of brevity

The first conversion circuit 111A may output a plurality of signals S11 to S22, from a first partial input signal PIS1 received via an input node IN. Each of the plurality of signals S11 to S22 having a target input impedance Z1 and different phases.

In the present disclosure, the first partial input signal PIS1 may be referred to as at least a portion of the input signal IS, as shown in FIG. 3.

That is, the first conversion circuit 111A may perform an impedance matching function to output the plurality of signals S11 S22, each having the target input impedance Z1, from the first partial input signal PIS1.

In addition, the first conversion circuit 111A may output signals in a differential relationship with each other from a single-phase first partial input signal PIS1. For example, the first conversion circuit 111A may output a first-first signal S11 and a first-second signal S12 in the differential relationship with each other from the single-phase first partial input signal PIS1.

Further, the first conversion circuit 111A may output signals that are orthogonal to each of the signals in the differential relationship. For instance, the first conversion circuit 111A may output a second-first signal S21 that is orthogonal to the first-first signal S11. The first conversion circuit 111A may output a second-second signal S22 that is orthogonal to the first-second signal S12.

According to the embodiment, the balanced amplifier circuit 100D1 may further include the third amplifier circuit AC3a connected to the second conversion circuit 112A.

That is, the balanced amplifier circuit 100D1 may include the third amplifier circuit AC3a that amplifies a second partial input signal PIS2 received via an additional input node AIN and outputs the amplified second partial input signal PIS2 as an amplification signal AS.

In the present disclosure, the second partial input signal PIS2 may be referred to as at least a portion of the input signal IS shown in FIG. 3. Accordingly, the first partial input signal PIS1 and the second partial input signal PIS2 may be referred to as signals separated from the input signal IS shown in FIG. 3. Further, the first partial input signal PIS1 and the second partial input signal PIS2 may be distinguished from each other in at least one of phase and magnitude.

The second partial input signal PIS2 may be understood as a single-phase signal.

According to the embodiment, the third amplifier circuit AC3a may include a third transistor amplifier ATR3 that amplifies the second partial input signal PIS2.

In addition, the third amplifier circuit AC3a may include a first additional capacitor CP1 connected in parallel to the third transistor amplifier ATR3 between a tenth node N10 and a ground.

In the present disclosure, the first additional capacitor CP1 may include a parasitic capacitor of the third transistor amplifier ATR3. The first additional capacitor CP1 may include the third capacitor C3 shown in FIG. 3. That is, the first additional capacitor CP1 may be referred to as a capacitor equivalent to a configuration obtained by combining the parasitic capacitor of the third transistor amplifier ATR3 and the third capacitor C3 shown in FIG. 3.

The balanced amplifier circuit 100D1 may include the second conversion circuit 112A that outputs an output signal OS from a first-third signal S13, a first-fourth signal S14, a second-third signal S23, a second-fourth signal S24, and the amplification signal AS.

For example, the second conversion circuit 112A may output the output signal OS having an output impedance Z3 from the first-third to second-fourth signals S13 to S24, each having a target output impedance Z2 and a 90-degree phase difference with respect to one another, and the amplification signal AS.

In the present disclosure, as the amplification signal AS is input to the second conversion circuit 112A, a load impedance in a direction from the first amplifier circuit AC1 and the second amplifier circuit AC2 towards the second conversion circuit 112A may change.

That is, the balanced amplifier circuit 100D1 may generate a load modulation through the third amplifier circuit AC3a that amplifies a portion of the input signal.

Accordingly, the balanced amplifier circuit 100D1, according to the present disclosure, may improve the power efficiency of the operation of amplifying and outputting the input signal, when compared to related amplifier circuits.

Referring to FIG. 9B, the balanced amplifier circuit 100D2 may further include the third amplifier circuit AC3b connected to a second conversion circuit 112E.

For example, the balanced amplifier circuit 100D2 may include the third amplifier circuit AC3b that amplifies a second-first partial input signal PIS2P received via a first additional input node AINP and a second-second partial input signal PIS2N received via a second additional input node AINN. In the present disclosure, the second-first partial input signal PIS2P and the second-second partial input signal PIS2N may have a differential relationship with each other.

According to an embodiment, the third amplifier circuit AC3b may amplify the second-first partial input signal PIS2P and may output the amplified second-first partial input signal PIS2P as a first amplification signal AS1. Further, the third amplifier circuit AC3b may amplify the second-second partial input signal PIS2N and may output the amplified second-second partial input signal PIS2N as a second amplification signal AS2.

That is, the third amplifier circuit AC3b may amplify the second-first partial input signal PIS2P and the second-second partial input signal PIS2N, which are in the differential relationship, and may output the amplified second-first partial input signal PIS2P and the amplified second-second partial input signal PIS2N as the first amplification signal AS1 and the second amplification signal AS2.

According to the embodiment, the third amplifier circuit AC3b may include a third transistor amplifier ATR3 that amplifies the second-first partial input signal PIS2P and the second-second partial input signal PIS2N.

The third amplifier circuit AC3a may include a first additional capacitor CP1 connected in parallel to the third transistor amplifier ATR3 between a tenth node N10 and an eleventh node N11.

In the present disclosure, the first additional capacitor CP1 may include a parasitic capacitor of the third transistor amplifier ATR3. In addition, the first additional capacitor CP1 may include the third capacitor C3 shown in FIG. 3. That is, the first additional capacitor CP1 may be referred as a capacitor equivalent to a configuration obtained by combining the parasitic capacitor of the third transistor amplifier ATR3 and the third capacitor C3 shown in FIG. 3.

The balanced amplifier circuit 100D2 may include the second conversion circuit 112E that outputs an output signal OS from a first-third signal S13, a first-fourth signal S14, a second-third signal S23, a second-fourth signal S24, the first amplification signal AS1, and the second amplification signal AS2.

The second conversion circuit 112E may include a fourth transformer T4, a fifth transformer T5, a sixth transformer T6, a seventh transformer T7, and a fourth capacitor C4.

For example, the second conversion circuit 112E may include the fourth transformer T4 connected between a first amplifier circuit AC1 and the third amplifier circuit AC3b. In addition, the second conversion circuit 112E may include the fifth transformer T5 connected between a second amplifier circuit AC2 and an output node ON.

Further, the second conversion circuit 112E may include the sixth transformer T6 connected between a sixth node N6 from which the first-third signal S13 is output and an eighth node N8 from which the second-third signal S23 is output and between a seventh node N7 from which the first-fourth signal S14 is output and a ninth node N9 from which the second-fourth signal S24 is output. In the present disclosure, the sixth transformer T6 may include an inductor connected between the sixth node N6 and the eighth node N8 and an inductor connected between the seventh node N7 and the ninth node N9.

The second conversion circuit 112E may include the seventh transformer T7 connected between the tenth node N10 and the output node ON and between the eleventh node N11 and the output node ON. For example, the seventh transformer T7 may include an inductor connected between the tenth node N10 and the eleventh node N11 and an inductor connected between the output node ON and a ground.

The second conversion circuit 112E may include the fourth capacitor C4 connected between the output node ON and the ground.

The second conversion circuit 112E may output the output signal OS having an output impedance Z3 from the first-third to second-fourth signals S13 to S24, each having a target output impedance Z2 and a 90-degree phase difference with respect to one another, the first amplification signal AS1, and the second amplification signal AS2.

In the present disclosure, as the first amplification signal AS1 and the second amplification signal AS2 are input to the second conversion circuit 112E, a load impedance in a direction from the first amplifier circuit AC1 and the second amplifier circuit AC2 towards the second conversion circuit 112E may change.

That is, according to the embodiment, the balanced amplifier circuit 100D2 may generate a load modulation through the third amplifier circuit AC3b that amplifies a portion of the input signal.

Accordingly, the balanced amplifier circuit 100D2, according to the present disclosure, may improve the power efficiency of the operation of amplifying and outputting the input signal, when compared to related amplifier circuits.

According to the configurations described above, the balanced amplifier circuit 100D2 may be implemented with a relatively smaller area compared to a case where a circuit for impedance conversion, a circuit to generate a single-phase signal from the signals in the differential relationship and from the signals having the 90-degree phase difference with each of the signals in the differential relationship are provided separately.

That is, according to the above-described configurations, the balanced amplifier circuit 100D2 may reduce the area that may be needed to implement the electronic device 10, when compared to related amplifier circuits.

Furthermore, the balanced amplifier circuit 100D2, according to the present disclosure, may include a relatively smaller number of passive elements compared to a case where a circuit for impedance conversion, a circuit to generate the single-phase signal from the signals in the differential relationship and from the signals having the 90-degree phase difference with each of the signals in the differential relationship are provided separately.

Accordingly, the balanced amplifier circuit 100D2, according to the present disclosure, may reduce power consumption due to the passive elements, when compared to related amplifier circuits. In addition, the balanced amplifier circuit 100D2 may improve output power and gain, when compared to related amplifier circuits.

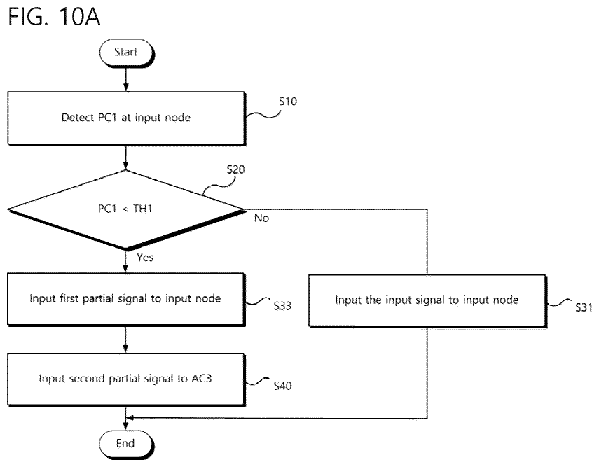

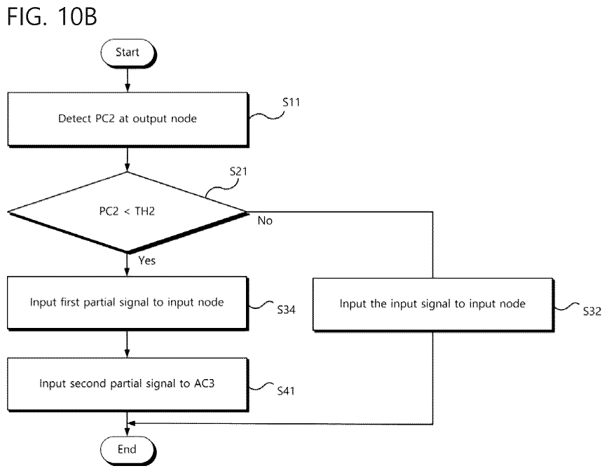

FIG. 10A is a flowchart showing a method of controlling an input signal based on a first power consumption consumed at an input node, according to an embodiment of the present disclosure. FIG. 10B is a flowchart showing a method of controlling an input signal based on a second power consumption consumed at an output node, according to an embodiment of the present disclosure.

Referring to FIGS. 10A and 10B, the processor 110 (or the electronic device 10) may control the signal input to the balanced amplifier circuit 100 based on the power consumption.

Referring to FIG. 10A, the processor 110 may control the signal input to the balanced amplifier circuit 100 based on the first power consumption PC1 consumed at the input node IN.

In operation S10, the processor 110 may detect the first power consumption PC1 consumed at the input node IN.

For example, the processor 110 may detect the first power consumption PC1 consumed at the input node IN while the balanced amplifier circuit 100 amplifies the input signal IS and outputs the amplified input signal as the output signal OS.

In the present disclosure, the electronic device 10 may further include a detecting circuit that detects the power consumed at least at one node of the balanced amplifier circuit 100. In addition, the detecting circuit may be electrically connected to the processor 110.

In operation S20, the processor 110 may determine whether the first power consumption PC1 is less than a first threshold value TH1. In the present disclosure, the first threshold value TH1 may be understood as a predetermined value with respect to the first power consumption PC1.

In operation S31, when the first power consumption PC1 is greater than or equal to the first threshold value TH1 (No in operation S20), the processor 110 may input the input signal IS to the input node IN.

For example, when the first power consumption PC1 is greater than or equal to the first threshold value TH1, the processor 110 may input the input signal IS, which may be needed to transmit the RF signal having a specified frequency through the antenna 130, to the input node IN.

In operation S33, when the first power consumption PC1 is less than the first threshold value TH1 (Yes in operation S20), the processor 110 may input the first partial input signal PIS1 to the input node IN.

In the present disclosure, the first partial input signal PIS1 may be understood as at least a portion of the signal (e.g., the input signal IS) input to the balanced amplifier circuit 100 to transmit the RF signal of the specified frequency through the antenna 130.

In addition, in operation S40, the processor 110 may input the second partial input signal PIS2 to the third amplifier circuit AC3a, AC3b.

For example, when the first power consumption PC1 is less than the first threshold value TH1, the processor 110 may input the second partial input signal PIS2 to the additional input node AIN of the third amplifier circuit AC3a, AC3b.

In the present disclosure, the second partial input signal PIS2 may be understood as at least a portion of the signal (e.g., the input signal IS) input to the balanced amplifier circuit 100 to transmit the RF signal of the specified frequency through the antenna 130.

In addition, the second partial input signal PIS2 may be distinguished from the first partial input signal PIS1 by at least one of magnitude and phase. That is, the first partial input signal PIS1 and the second partial input signal PIS2 may constitute the input signal IS that may be needed to transmit the RF signal of the specified frequency through the antenna 130.

In the present disclosure, the order in which operations S33 and S40 are performed should not be limited to that shown in FIG. 10A, and at least portions of operation S33 and operation S40 may be performed simultaneously.

That is, when the first power consumption PC1 is less than the first threshold value TH1, the processor 110 may input a portion of the signal, which may be needed to transmit the RF signal with the specified frequency through the antenna 130, to the input node IN and may input another portion to the additional input node AIN.

Referring to FIG. 10B, the processor 110 may control the signal input to the balanced amplifier circuit 100 based on the second power consumption PC2 consumed at the output node ON.

In operation S11, the processor 110 may detect the second power consumption PC2 consumed at the output node ON.

For example, the processor 110 may detect the second power consumption PC2 consumed at the output node ON during a process in which the balanced amplifier circuit 100 amplifies the input signal IS and outputs the amplified input signal as the output signal OS.

In operation S21, the processor 110 may determine whether the second power consumption PC2 is less than a second threshold value TH2. In the present disclosure, the second threshold value TH2 may be a predetermined value with respect to the second power consumption PC2.

In operation S32, when the second power consumption PC2 is greater than or equal to the second threshold value TH2 (No in operation S21), the processor 110 may input the input signal IS to the input node IN.

For example, when the second power consumption PC2 is greater than or equal to the second threshold value TH2, the processor 110 may input the input signal IS, which may be needed to transmit the RF signal with the specified frequency through the antenna 130, to the input node IN.

In operation S34, when the second power consumption PC2 is less than the second threshold value TH2 (Yes in operation S21), the processor 110 may input the first partial input signal PIS1 to the input node IN.

In operation S41, the processor 110 may input the second partial input signal PIS2 to the third amplifier circuit AC3a, AC3b.

For example, when the second power consumption PC2 is less than the second threshold value TH2, the processor 110 may input the second partial input signal PIS2 to the additional input node AIN of the third amplifier circuit AC3a, AC3b.

In the present disclosure, the second partial input signal PIS2 may be understood as a portion of the signal input to the balanced amplifier circuit 100 to transmit the RF signal with the specified frequency through the antenna 130.

In addition, the second partial input signal PIS2 may be distinguished from the first partial input signal PIS1 by at least one of magnitude and phase. That is, the first partial input signal PIS1 and the second partial input signal PIS2 may constitute the input signal IS that may be needed to transmit the RF signal of the specified frequency through the antenna 130.

In the present disclosure, the order in which operations S34 and S41 are performed should not be limited to that shown in FIG. 10B, and at least portions of operation S34 and operation S41 may be performed simultaneously.

That is, when the second power consumption PC2 is less than the second threshold value TH2, the processor 110 may input a portion of the signal, which may be needed to transmit the RF signal with the specified frequency through the antenna 130, to the input node IN and may input another portion to the additional input node AIN.

In addition, the third amplifier circuit AC3a, AC3b may amplify the second partial input signal PIS2 to output the amplified second partial input signal as the amplification signal AS.

Further, the second conversion circuit 112 may output the output signal OS from the first-third signal S13, the first-fourth signal S14, the second-third signal S23, the second-fourth signal S24, and the amplification signal AS.

In the present disclosure, as the amplification signal AS is input to the second conversion circuit 112, the load impedance in the direction from the first amplifier circuit AC1 and the second amplifier circuit AC2 towards the second conversion circuit 112 may change.

That is, when the first power consumption PC1 is less than the first threshold value TH1, the processor 110 may input the portion of the signal (e.g., the input signal IS), which may be needed to transmit the RF signal, to the third amplifier circuit AC3a, AC3b and thus may generate the load modulation.

Accordingly, the electronic device 10 may improve the power efficiency of the operation of transmitting the RF signal, when compared to related amplifier circuits.

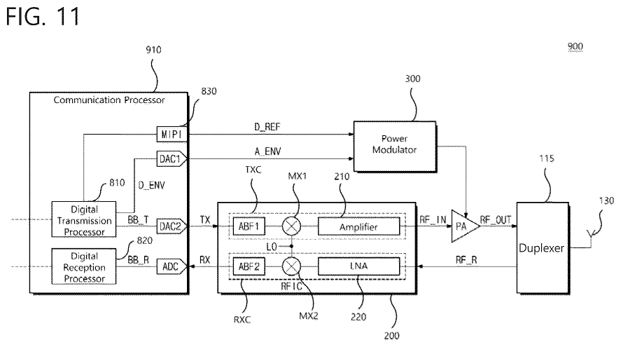

FIG. 11 is a block diagram showing a wireless communication device, according to an embodiment of the present disclosure.

Referring to FIG. 11, the wireless communication device 900 may include a communication processor 910, an RFIC 200, a power modulator 300, a duplexer 115, a power amplifier PA, and an antenna 130.

The wireless communication device 900, and its components, as shown in FIG. 11 may include and/or may be similar in many respects the electronic device 10 and its components shown in FIG. 1, and may include additional features not mentioned above. Consequently, repeated descriptions of the wireless communication device 900 described above with reference to FIG. 1 may be omitted for the sake of brevity.

The communication processor 910 may process a baseband signal BB_T according to an established communication method via an internal digital transmission processor 810. In addition, the communication processor 910 may process a received baseband signal BB_R according to an established communication method via a digital reception processor 820. In an embodiment, the communication processor 910 may have a substantially similar and/or the same configuration as the processor 110 shown in FIG. 1.

For example, the communication processor 910 may process a signal to be transmitted or a received signal according to communication methods such as, but not limited to, OFDM (Orthogonal Frequency Division Multiplexing), OFDMA (Orthogonal Frequency Division Multiple Access), WCDMA (Wideband Code Division Multiple Access), HSPA+ (High Speed Packet Access+), or the like. In addition, the communication processor 910 may process the baseband signal BB_T or BB_R according to various types of communication methods, that is, various communication methods to which technology for modulating or demodulating an amplitude and frequency of the baseband signal BB_T or BB_R is applied.

The communication processor 910 may extract an envelope of the baseband signal BB_T via the digital transmission processor 810 and may generate a digital envelope signal D_ENV based on the extracted envelope. In addition, the communication processor 910 may generate an average power signal D_REF based on an average power tracking table stored in a memory. In the present disclosure, the extracted envelope may correspond to an amplitude component of the baseband signal BB_T, that is, the magnitude of the I signal and the Q signal.

In the present disclosure, the communication processor 910 may perform a digital-to-analog conversion on the baseband signal BB_T and the digital envelope signal D_ENV using a plurality of internal digital-to-analog converters DAC1 and DAC2 to generate an analog transmission signal TX and an analog envelope signal A_ENV. That is, the average power signal D_REF output from the communication processor 910 may be a digital signal. Accordingly, the average power signal D_REF may be provided to a digital-to-analog converter included in the power modulator 300 via an MIPI 830 and may be converted into an analog signal, for example, a reference voltage signal, through the digital-to-analog converter included in the power modulator 300. The digital-to-analog converters DAC1 and DAC2 included in the communication processor 910 may operate at a relatively higher speed than the digital-to-analog converter included in the power modulator 300.

However, the present disclosure should not be limited thereto or thereby, and the communication processor 910 may convert and output the average power signal D_REF as an analog signal through the internal digital-to-analog converter. In such an embodiment, the communication processor 910 may provide the average power signal, which is converted to an analog signal, to the power modulator 300 as a reference voltage signal.

For convenience of explanation, the communication processor 910 may be described as providing the average power signal D_REF to the digital-to-analog converter included in the power modulator 300 via the MIPI 830. However, embodiments of the present disclosure are not limited thereto.

The transmission signal TX and the analog envelope signal A_ENV may be differential signals including a positive signal and a negative signal, respectively.

In addition, the communication processor 910 may receive a reception signal RX, which is an analog signal, from the RFIC 200. The communication processor 910 may extract the baseband signal BB_R, which is a digital signal, by performing analog-to-digital conversion on the reception signal RX via the internal analog-to-digital converter ADC. In such an embodiment, the reception signal RX may be a differential signal including a positive signal and a negative signal.

The RFIC 200 may generate an RF input signal RF_IN by performing frequency up-conversion on the transmission signal TX or may generate the reception signal RX by performing frequency down-conversion on an RF reception signal RF_R. For example, the RFIC 200 may include a transmission circuit TXC for the frequency up-conversion, a reception circuit RXC for the frequency down-conversion, and a local oscillator LO.

In the present disclosure, the transmission circuit TXC may include a first analog baseband filter ABF1, a first mixer MX1, and an amplifier 210. For example, the first analog baseband filter ABF1 may include a low pass filter.

The first analog baseband filter ABF1 may filter the transmission signal TX received from the communication processor 910 and may provide the filtered transmission signal TX to the first mixer MX1. In addition, the first mixer MX1 may perform the frequency up-conversion, which converts the frequency of the transmission signal TX from a baseband to a high-frequency band in response to a frequency signal provided by the local oscillator LO. Through the frequency up-conversion, the transmission signal TX may be provided to the amplifier 210 as the RF input signal RF_IN, and the amplifier 210 may perform a primary power amplification of the RF input signal RF_IN and provide the amplified RF input signal RF_IN to the power amplifier PA.

According to an embodiment, the amplifier 210 shown in FIG. 11 may include the balanced amplifier circuit 100 shown in FIG. 1.

Therefore, the balanced amplifier circuit 100 (or the amplifier 210) may include the first conversion circuit 111 that outputs the signals S11 and S12, which have the target input impedance Z1 and are in the differential relationship with each other, and the signals S11 and S21, which have the 90-degree phase difference with each other, from the single-phase input signal IS.

That is, the balanced amplifier circuit 100, according to the present disclosure, may be implemented with a relatively smaller area compared to the case where the circuit for impedance conversion, the circuit to generate the signals in the differential relationship, and the circuit to generate the signals having the 90-degree phase difference are provided separately.

That is, according to the above-described configurations, the balanced amplifier circuit 100 may reduce the area that may be needed to implement the wireless communication device 900, when compared to related amplifier circuits.

In addition, the balanced amplifier circuit 100 may include the first amplifier circuit AC1 and the second amplifier circuit AC2 that amplify at least a portion of the plurality of signals S11 to S22.

Further, the balanced amplifier circuit 100 may include the second conversion circuit 112 that outputs the single-phase output signal OS having the output impedance Z3 from the first-third to second-fourth signals S13 to S24 amplified through the first and second amplifier circuits AC1 and AC2.

That is, the balanced amplifier circuit 100, according to the present disclosure, may include the relatively smaller number of passive elements compared to the case where the circuit for impedance conversion, the circuit to generate the signals in the differential relationship, and the circuit to generate the single-phase signal from the signals in the differential relationship and the signals having the 90-degree phase difference with each of the signals in the differential relationship are provided separately.

Therefore, the balanced amplifier circuit 100, according to the present disclosure, may reduce power consumption due to the passive elements, when compared to related amplifier circuits. In addition, the balanced amplifier circuit 100 may improve output power and gain, when compared to related amplifier circuits.

The power amplifier PA may receive a power supply voltage, that is, a dynamically variable output voltage, from the power modulator 300 and may perform a secondary power amplification of the RF input signal RF_IN based on the received power supply voltage to generate an RF output signal RF_OUT. The power amplifier PA may provide the generated RF output signal RF_OUT to the duplexer 115.

According to an embodiment, the balanced amplifier circuit 100 of FIG. 1 may be included in the power amplifier PA shown in FIG. 11.

The reception circuit RXC may include a second analog baseband filter ABF2, a second mixer MX2, and a low-noise amplifier 220. For example, the second analog baseband filter ABF2 may include a low-pass filter.

The low-noise amplifier 220 may amplify the RF reception signal RF_R received from the duplexer 115 and may provide the amplified RF reception signal RF_R to the second mixer MX2. The second mixer MX2 may perform frequency down-conversion to convert the frequency of the reception signal RF_R from a high-frequency band to a baseband using a frequency signal provided by the local oscillator LO. Through the frequency down-conversion, the RF reception signal RF_R may be provided to the second analog baseband filter ABF2 as the reception signal RX, and the second analog baseband filter ABF2 may filter the reception signal RX and may provide the filtered reception signal RX to the communication processor 910.

The power modulator 300 may generate a modulated output voltage whose level dynamically changes based on the analog envelope signal A_ENV and the average power signal D_REF and may provide the modulated output voltage to the power amplifier PA as the power supply voltage.

For example, the power modulator 300 may receive the average power signal D_REF and the analog envelope signal A_ENV from the communication processor 910. The power modulator 300 may be driven in one of an ET mode and an APT mode based on the received average power signal D_REF and analog envelope signal A_ENV to generate the dynamically variable output voltage. In addition, the power modulator 300 may supply the generated output voltage to the power amplifier PA as the power supply voltage.

When the power supply voltage having a fixed level is applied to the power amplifier PA, the power efficiency of the power amplifier PA may be degraded. Therefore, for efficient power management of the power amplifier PA, the power modulator 300 may modulate the input voltage (e.g., the power supplied from a battery) based on at least one of the analog envelope signal A_ENV and the average power signal D_REF and may provide the modulated input voltage as the power supply voltage to the power amplifier PA.

The wireless communication device 900 may include the duplexer 115 that is capable of separating a transmission frequency and a reception frequency. For example, the duplexer 115 may separate the RF output signal RF_OUT provided from the power amplifier PA for each frequency band and may provide the RF output signal RF_OUT to a corresponding antenna 130. In addition, the duplexer 115 may provide external signals provided from the antenna 130 to the low-noise amplifier 220 of the reception circuit RXC of the RFIC 200. For example, the duplexer 115 may include a front-end module with integrated duplexer (FEMiD).

The antenna 130 may transmit the RF output signal RF_OUT externally or may provide the RF reception signal RF_R provided from the external sources to the RFIC 200. For example, the antenna 130 may be referred to as a 1T1R antenna, but it should not be limited thereto or thereby.

Each of the communication processor 910, the power modulator 300, RFIC 200, the power amplifier PA, and the duplexer 115 may be individually implemented as an IC, chip, or module. In addition, the communication processor 910, the power modulator 300, the RFIC 200, the power amplifier PA, and the duplexer 115 may be mounted together on a printed circuit board (PCB). However, the technical spirit of the present disclosure is not limited thereto, and in some embodiments, at least some of the communication processor 910, the power modulator 300, the RFIC 200, the power amplifier PA, and the duplexer 115 may be implemented as a single communication chip.

Furthermore, the wireless communication device 900 shown in FIG. 11 may be included in a wireless communication system using a cellular network such as, but not limited to, 5^{th} generation (5G), Long Term Evolution (LTE), or the like, and/or may be included in a wireless local area network (WLAN) system or any other arbitrary wireless communication system. The configuration of the wireless communication device 900 shown in FIG. 11 is merely an example and may be variously configured according to communication protocols or communication methods.

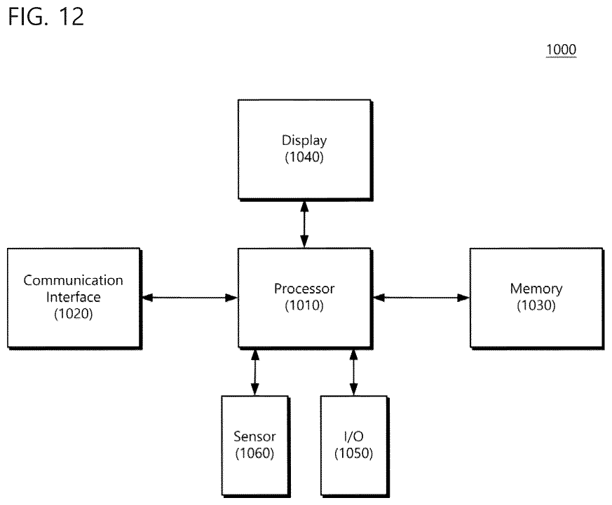

FIG. 12 is a block diagram showing an Internet of Things (IoT) device including the electronic device, according to an embodiment of the present disclosure.

Referring to FIG. 12, the term IoT may refer to a network between objects using wired or wireless communication. The IoT device 1000 may have an accessible wired or wireless interface and may include devices that communicate with at least one other device via the wired or wireless interface to transmit or receive data. The accessible interface of the IoT device 1000 may include a wired local area network (LAN), a wireless local area network (WLAN) such as, but not limited to, wireless fidelity (Wi-Fi), a wireless personal area network (WPAN) such as, but not limited to, Bluetooth™, a wireless universal serial bus (USB), ZigBee, near field communication (NFC), radio-frequency identification (RFID), power line communication (PLC), or a modem communication interface, e.g., third generation (3G), long term evolution (LTE), fourth generation (4G), or fifth generation (5G), which may access a mobile cellular network. The Bluetooth interface may support Bluetooth low energy (BLE) communications.

In particular, the IoT device 1000 may include a communication interface 1020 to communicate with an external device. The communication interface 1020 may be, for example, a wired local area network (LAN), a wireless local area communication interface, such as, but not limited to, Bluetooth™, Wi-Fi, ZigBee, or the like, or a modem communication interface, which may access PLC or a mobile cellular network, such as, but not limited to, 3G, LTE, 4G, 5G, or the like.

The IoT device 1000, according to an embodiment, may include and/or may be similar in many respects to the electronic device 10 shown in FIG. 1, and may include additional features not mentioned above. Consequently, repeated descriptions of the IoT device 1000 described above with reference to FIG. 1 may be omitted for the sake of brevity.

The communication interface 1020 may include a transmitter and/or a receiver. Here, the communication interface 1020 shown in FIG. 12 may be understood to include the RFFE 120 and the antenna 130 shown in FIG. 1.

For example, the communication interface 1020 may include the balanced amplifier circuit 100 that amplifies the signal to transmit the RF signal through the antenna 130.

In the present disclosure, the balanced amplifier circuit 100 may include the first conversion circuit 111 that outputs the signals S11 and S12, each having the target input impedance Z1 and differential relationship, and the signals S11 and S21, which have the 90-degree phase difference with each other, from the single-phase input signal IS.

That is, the balanced amplifier circuit 100, according to the present disclosure, may be implemented with the relatively small area compared to the case where the circuit for impedance conversion, the circuit to generate the differential signals, and the circuit to generate the signals with the 90-degree phase difference are provided separately.

That is, according to the above-described configurations, the balanced amplifier circuit 100 may reduce the area that may be needed to implement the IoT device 1000, when compared to related amplifier circuits.

In addition, the balanced amplifier circuit 100 may include the first amplifier circuit AC1 and the second amplifier circuit AC2, which amplify at least a portion of the plurality of signals S11 to S22.

Further, the balanced amplifier circuit 100 may include the second conversion circuit 112 that outputs the single-phase output signal OS having the output impedance Z3 from the first-third to second-fourth signals S13 to S24 amplified through the first and second amplifier circuits AC1 and AC2.

That is, the balanced amplifier circuit 100, according to the present disclosure, may include a relatively smaller number of passive elements compared to the case where the circuit for impedance conversion, the circuit to generate the differential signals, and the circuit to generate the single-phase signal from each of the differential signals having the 90-degree phase difference are provided separately.

Therefore, the balanced amplifier circuit 100, according to the present disclosure, may reduce power consumption due to the passive elements, when compared to related amplifier circuits. The balanced amplifier circuit 100 may improve output power and gain, when compared to related amplifier circuits.

The IoT device 1000 may transmit and/or receive information from an access point or a gateway via a transmitter and/or a receiver. In addition, the IoT device 1000 may communicate with a user device or another IoT device to transmit and/or receive control information or data of the IoT device 1000.

The IoT device 1000 may include a processor 1010 that performs operations. In the present disclosure, the processor 1010 shown in FIG. 12 may have a substantially similar and/or the same configuration as the processor 110 shown in FIG. 1, and may include additional features not mentioned above. Consequently, repeated descriptions of the processor 1010 described above with reference to FIG. 1 may be omitted for the sake of brevity.

The IoT device 1000 may further include a power supply unit that includes a built-in battery for internal power supply or receives power from an external source. In addition, the IoT device 1000 may include a display 1040 to display an internal status or data. A user may control the IoT device 1000 through a user interface (UI) of the display 1040 of the IoT device 1000. The IoT device 1000 may transmit the internal status and/or data externally via the transmitter and may receive control commands and/or data from the external source via the receiver.

A memory 1030 may store control command codes, control data, or user data for controlling the IoT device 1000. The memory 1030 may include at least one of a volatile memory or a non-volatile memory. The non-volatile memory may include at least one of various memories such as, but not limited to, a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (ReRAM), or a ferroelectric RAM (FRAM). The volatile memory may include at least one of various memories such as, but not limited to, a dynamic RAM (DRAM), a static RAM (SRAM), or a synchronous DRAM (SDRAM).

The IoT device 1000 may further include a storage device. The storage device may include at least one of non-volatile media such as, but not limited to, a hard disk drive (HDD), a solid state drive (SSD), an embedded multi-media card (eMMC), or a universal flash storage (UFS). The storage device may store user information provided via an input/output unit (I/O) 1050 and sensing information collected via a sensor 1060.

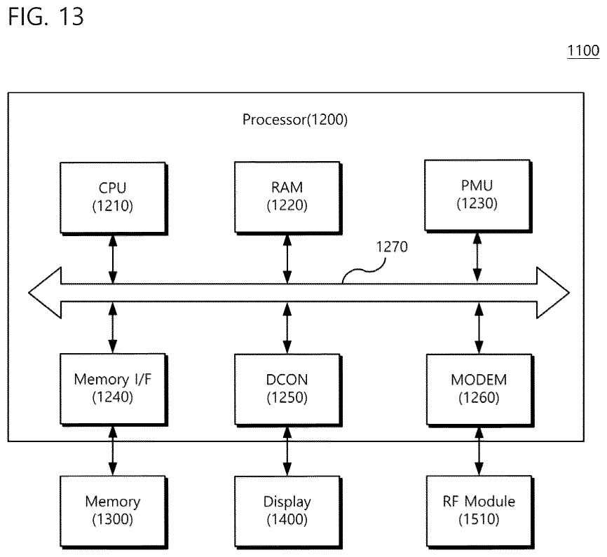

FIG. 13 is a block diagram showing a mobile terminal to which an electronic device, according to an embodiment of the present disclosure, is applied.

Referring to FIG. 13, the mobile terminal 1100 may include a processor 1200, a memory 1300, a display 1400, and a radio frequency (RF) module 1510. In addition, the mobile terminal 1100 may include various components such as, but not limited to, a lens, a sensor, an audio module, or the like.

The processor 1200 may be implemented as a system on chip (SoC) and may include a central processing unit (CPU) 1210, an RAM 1220, a power management unit (PMU) 1230, a memory interface (memory I/F) 1240, a display controller (DCON) 1250, a modem 1260, and a bus 1270. The processor 1200 may further include various other IPs. The processor 1200 may be referred to as a ModAP as functions of a modem chip are integrated in the processor 1200, but it should not be limited thereto or thereby.

In the present disclosure, the processor 1200 shown in FIG. 13 may include and/or may be similar in many respects to the processor 110 shown in FIG. 1, and may include additional features not mentioned above. Consequently, repeated descriptions of the processor 1200 described above with reference to FIG. 1 may be omitted for the sake of brevity.

The CPU 1210 may control the overall operation of the processor 1200 and the mobile terminal 1100. The CPU 1210 may control the operation of each component of the processor 1200. In addition, the CPU 1210 may be implemented as a multi-core. The multi-core may be a single computing component having two or more independent cores.

The RAM 1220 may temporarily store programs, data, or instructions. For example, programs and/or data stored in the memory 1300 may be temporarily stored in the RAM 1220 according to the control of the CPU 1210 or a booting code. The RAM 1220 may be implemented as DRAM or SRAM.

The PMU 1230 may manage the power of each component of the processor 1200. The PMU 1230 may determine the operational status of each component of the processor 1200 and may control the operation of each component of the processor 1200.

The memory interface 1240 may control the overall operation of the memory 1300 and may control data exchange between each component of the processor 1200 and the memory 1300. The memory interface 1240 may write data in the memory 1300 or read data from the memory 1300 according to a request from the CPU 1210.

The display controller 1250 may transmit image data to be displayed on the display 1400 to the display 1400. The display 1400 may be implemented as a flat panel display or a flexible display, such as, but not limited to, a liquid crystal display (LCD), an OLED (organic light emitting diode) display, or the like.

The modem 1260, for wireless communication, may modulate data, which is to be transmitted, to be suitable for a wireless environment and may recover the received data. The modem 1260 may perform digital communication with the RF module 1510.

According to an embodiment, the RF module 1510 may be electrically connected to the antenna 130 shown in FIG. 1. In addition, the modem 1260 may include the balanced amplifier circuit 100 shown in FIG. 1.

In such an embodiment, the balanced amplifier circuit 100 may include the first conversion circuit 111 that outputs the signals S11 and S12, which have the target input impedance Z1 and are in the differential relationship with each other, and the signals S11 and S21, which have the 90-degree phase difference with each other, from the single-phase input signal IS.

That is, the balanced amplifier circuit 100, according to the present disclosure, may be implemented with the relatively small area compared to the case where the circuit for impedance conversion, the circuit to generate the signals in the differential relationship, and the circuit to generate the signals having the 90-degree phase difference are provided separately.

That is, according to the above-described configurations, the balanced amplifier circuit 100 may reduce the area that may be needed to implement the mobile terminal 1100, when compared to related amplifier circuits.

In addition, the balanced amplifier circuit 100 may include the first amplifier circuit AC1 and the second amplifier circuit AC2, which amplify at least the portion of the plurality of signals S11 to S22.

Further, the balanced amplifier circuit 100 may include the second conversion circuit 112 that outputs the single-phase output signal OS having the output impedance Z3 from the first-third to second-fourth signals S13 to S24, which have the target output impedance Z2 and the different phases from one another.

That is, the balanced amplifier circuit 100, according to the present disclosure, may include the relatively smaller number of passive elements compared to the case where the circuit for impedance conversion, the circuit to generate the single-phase signal from the signals in the differential relationship and the signals having the 90-degree phase difference with respect to each of the signals in the differential relationship are provided separately.

Therefore, the balanced amplifier circuit 100, according to the present disclosure, may reduce power consumption due to the passive elements, when compared to related amplifier circuits. Also, the balanced amplifier circuit 100 may improve output power and gain, when compared to related amplifier circuits.

Accordingly, the RF module 1510 may convert the high frequency signal received via the antenna 130 into the low frequency signal and may transmit the converted low frequency signal to the modem 1260. Further, the RF module 1510 may convert the low frequency signal received from the modem 1260 into the high frequency signal and may transmit the converted high frequency signal to the outside of the mobile terminal 1100 via the antenna 130. The RF module 1510 may amplify or filter signals.

As described above, the balanced amplifier circuit 100, according to the present disclosure, may include the first conversion circuit 111 that outputs the plurality of signals S11 to S22, each having the target input impedance Z1 and different phases, from the single-phase input signal IS.

That is, the balanced amplifier circuit 100, according to the present disclosure, may be implemented with the relatively small area compared to the case where the circuit for impedance conversion, the circuit to generate the differential signals, and the circuit to generate the signals having the 90-degree phase difference are provided separately.

That is, according to the above-described configurations, the balanced amplifier circuit 100 may reduce the area that may be needed to implement the mobile terminal 1100, when compared to related amplifier circuits.

In addition, the balanced amplifier circuit 100 may include the first amplifier circuit AC1 and the second amplifier circuit AC2, which amplify at least the portion of the plurality of signals S11 to S22.

Further, the balanced amplifier circuit 100 may include the second conversion circuit 112 that outputs the single-phase output signal OS having the output impedance Z3 from the first-third to second-fourth signals S13 to S24, each having the target output impedance Z2 and different phases.

That is, the balanced amplifier circuit 100, according to the present disclosure, may include the relatively smaller number of passive elements compared to the case where the circuit for impedance conversion and the circuit to generate the single-phase signal from the signals in the differential relationship and the signals having the 90-degree phase difference with respect to each of the differential signals are provided separately.

Therefore, the balanced amplifier circuit 100, according to the present disclosure, may reduce power consumption due to the passive elements, when compared to related amplifier circuits. Also, the balanced amplifier circuit 100 may improve output power and gain, when compared to related amplifier circuits.

Although the embodiments of the present disclosure have been described, it is to be understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present disclosure may be determined according to the attached claims.

What is claimed is:

1. A balanced amplifier circuit, comprising:
a first conversion circuit configured to output, based on an input signal having an input impedance, a first-first signal, a first-second signal, a second-first signal, and a second-second signal, the first-first signal having a 90-degree phase difference from the second-first signal, the first-second signal having a first differential relationship with the first-first signal, and the second-second signal having a second differential relationship with the second-first signal;
a first amplifier circuit configured to:
amplify the first-first signal to output a first-third signal, and
amplify the first-second signal to output a first-fourth signal;
a second amplifier circuit configured to:
amplify the second-first signal to output a second-third signal, and
amplify the second-second signal to output a second-fourth signal; and
a second conversion circuit configured to output an output signal, having an output impedance, based on the first-third signal, the first-fourth signal, the second-third signal, and the second-fourth signal,
wherein each of the first-first signal, the first-second signal, the second-first signal, and the second-second signal has a target input impedance.

2. The balanced amplifier circuit of claim 1, further comprising:
an input resistor coupled between the first conversion circuit and a ground; and
an output resistor coupled between the second conversion circuit and the ground.

3. The balanced amplifier circuit of claim 2, wherein the first conversion circuit further comprises:
a first transformer coupled between an input node to which the input signal is input and the first amplifier circuit;
a second transformer coupled between the input resistor and the second amplifier circuit;
a first capacitor coupled between the input node and the ground;
a second capacitor coupled between a first node and the ground, the first node being between the input resistor and the second transformer;
a first inductor coupled between the input node and the first node; and
a third transformer coupled between a second node and a fourth node, and between a third node and a fifth node,
wherein the first-first signal is output from the second node,
wherein the second-first signal is output from the fourth node,
wherein the first-second signal is output from the third node, and
wherein the second-second signal is output from the fifth node.

4. The balanced amplifier circuit of claim 3, wherein the second conversion circuit further comprises:
a fourth transformer coupled between the first amplifier circuit and the output resistor;
a fifth transformer coupled between the second amplifier circuit and an output node;
a sixth transformer coupled between a sixth node and an eighth node and between a seventh node and a ninth node;
a third capacitor coupled between a tenth node and the ground;
a fourth capacitor coupled between the output node and the ground; and
a second inductor coupled between the tenth node and the output node,
wherein the output signal is output from the output node,
wherein the first-third signal is output from the sixth node,
wherein the first-fourth signal is output from the seventh node,
wherein the second-third signal is output from the eighth node,
wherein the second-fourth signal is output from the ninth node, and
wherein the tenth node is between the fourth transformer and the output resistor.

5. The balanced amplifier circuit of claim 4, wherein the first amplifier circuit further comprises:
a first amplifier transistor configured to amplify the first-first signal and the first-second signal;
a first input parasitic capacitor coupled in parallel with the first amplifier transistor between the second node and the third node; and
a first output parasitic capacitor coupled in parallel with the first amplifier transistor between the sixth node and the seventh node.

6. The balanced amplifier circuit of claim 4, wherein the first amplifier circuit further comprises:
a first amplifier configured to amplify the first-first signal; and
a second amplifier configured to amplify the first-second signal.

7. The balanced amplifier circuit of claim 6, wherein the first conversion circuit further comprises:
a first equivalent capacitor coupled between the second node and the third node; and
a second equivalent capacitor coupled between the fourth node and the fifth node.

8. The balanced amplifier circuit of claim 1, further comprising:
a third amplifier circuit coupled to the second conversion circuit,
wherein the third amplifier circuit is configured to amplify a signal input thereto via an additional input node and to output an amplification signal, and
wherein the second conversion circuit is configured to output the output signal based on the first-third signal, the first-fourth signal, the second-third signal, the second-fourth signal, and the amplification signal.

9. The balanced amplifier circuit of claim 2, wherein each of the first-third signal, the first-fourth signal, the second-third signal, and the second-fourth signal has a target output impedance,
wherein the input resistor has an input resistance value corresponding to half of the target input impedance, and
wherein the output resistor has an output resistance value corresponding to half of the target output impedance.

10. An electronic device, comprising:
a balanced amplifier circuit configured to amplify an input signal having an input impedance and to output an output signal having an output impedance; and
a processor configured to control the balanced amplifier circuit,
wherein the balanced amplifier circuit comprises:
a first conversion circuit configured to output, based on the input signal provided by the processor, a first-first signal, a first-second signal, a second-first signal, and a second-second signal, the first-first signal having a 90-degree phase difference from the second-first signal, the first-second signal having a first differential relationship with the first-first signal, and the second-second signal having a second differential relationship with the second-first signal;
a first amplifier circuit configured to amplify the first-first signal to output a first-third signal, and to amplify the first-second signal to output a first-fourth signal;
a second amplifier circuit configured to amplify the second-first signal to output a second-third signal, and to amplify the second-second signal to output a second-fourth signal; and
a second conversion circuit configured to output the output signal, via an output node, based on the first-third signal, the first-fourth signal, the second-third signal, and the second-fourth signal,
wherein each of the first-first signal, the first-second signal, the second-first signal, and the second-second signal has a target input impedance.

11. The electronic device of claim 10, wherein the balanced amplifier circuit further comprises:
an input resistor coupled between the first conversion circuit and a ground; and
a third amplifier circuit coupled to the second conversion circuit.

12. The electronic device of claim 11, wherein the processor is configured to, based on a first power consumption consumed at an input node being less than a first threshold value, input a first partial input signal of the input signal to the input node, and to input a second partial input signal of the input signal to the third amplifier circuit,
wherein the balanced amplifier circuit is configured to input the input signal at the input node, and
wherein the second partial input signal differs from the first partial input signal by at least one of a phase or a magnitude.

13. The electronic device of claim 12, wherein the processor is configured to, based on a second power consumption consumed at the output node being less than a second threshold value, input the first partial input signal to the input node, and to input the second partial input signal to the third amplifier circuit.

14. The electronic device of claim 12, wherein the first conversion circuit further comprises:
a first transformer coupled between the input node and the first amplifier circuit;
a second transformer coupled between the input resistor and the second amplifier circuit;
a first capacitor coupled between the input node and the ground;
a second capacitor coupled between a first node and the ground;
a first inductor coupled between the input node and the first node; and
a third transformer coupled between a second node and a fourth node and between a third node and a fifth node,
wherein the first node is between the input resistor and the second transformer,
wherein the first-first signal is output from the second node,
wherein the first-second signal is output from the third node,
wherein the second-first signal is output from the fourth node, and
wherein the second-second signal is output from the fifth node.

15. The electronic device of claim 14, wherein the second conversion circuit further comprises:
a fourth transformer coupled between the first amplifier circuit and the third amplifier circuit;
a fifth transformer coupled between the second amplifier circuit and the output node;
a sixth transformer coupled between a sixth node and an eighth node and between a seventh node and a ninth node;
a third capacitor coupled between a tenth node and the ground;
a fourth capacitor coupled between the output node and the ground; and
a second inductor coupled between the tenth node and the output node,
wherein the output signal is output from the output node,
wherein the first-third signal is output from the sixth node,
wherein the first-fourth signal is output from the seventh node,
wherein the second-third signal is output from the eighth node,
wherein the second-fourth signal is output from the ninth node, and
wherein the tenth node is between the fourth transformer and an output resistor.

16. The electronic device of claim 15, wherein the first amplifier circuit further comprises:
a first amplifier transistor;
a first input parasitic capacitor coupled in parallel with the first amplifier transistor between the second node and the third node; and
a first output parasitic capacitor coupled in parallel with the first amplifier transistor between the sixth node and the seventh node.

17. The electronic device of claim 10, further comprising:
an antenna configured to transmit a radio frequency (RF) signal of a predetermined frequency band based on the output signal output by the balanced amplifier circuit.

18. A conversion circuit for outputting a plurality of output signals based on an input signal having an input impedance, comprising:
a first capacitor coupled between an input node configured to receive the input signal and a ground;
a first inductor coupled between the input node and a first node;
a first transformer coupled between the input node and a second node and between the input node and a third node;
a second transformer coupled between the first node and a fourth node and between the first node and a fifth node;
a third transformer coupled between the second node and the fourth node and between the third node and the fifth node; and
a second capacitor coupled between the first node and the ground,
wherein each of the plurality of output signals has a target input impedance and a 90-degree phase difference with respect to one another,
wherein a first-first output signal of the plurality of output signals is output from the second node,
wherein a first-second output signal of the plurality of output signals is output from the third node,
wherein a second-first output signal of the plurality of output signals is output from the fourth node,
wherein a second-second output signal of the plurality of output signals is output from the fifth node,
wherein the first-second output signal has a first differential relationship with the first-first output signal, and
wherein the second-first output signal has a second differential relationship with the second-second output signal.

19. The conversion circuit of claim 18, further comprising:
a first equivalent capacitor coupled between the second node and the third node; and
a second equivalent capacitor coupled between the fourth node and the fifth node.

20. The conversion circuit of claim 18, further comprising:
an input resistor coupled between the first node and the ground,
wherein the input resistor has a resistance value corresponding to half of the target input impedance.
